(19) United States
(12) Patent Application Publication
(10) Pub. No.: US 2026/0313961 A1
(43) Pub. Date: Oct. 8, 2026

(54) SEMICONDUCTOR DEVICE INCLUDING CONDUCTIVE LAYERS AND CELL CAPACITOR

(71) Applicant: Samsung Electronics Co., Ltd., Suwon-si (KR)

(72) Inventors: Jinmyung Choi, Suwon-si (KR); Dongho Ahn, Suwon-si (KR); Minseo Yoon, Suwon-si (KR); Jinwoo Lee, Suwon-si (KR); Hideki Horii, Suwon-si (KR)

(73) Assignee: Samsung Electronics Co., Ltd., Suwon-si (KR)

(21) Appl. No.: 19/640,269

(22) Filed: Apr. 6, 2026

(30) Foreign Application Priority Data
Apr. 8, 2025 (KR) 10-2025-0045623

(51) Int. Cl. H10D 30/67; H10B 12/00; H10W 20/41

(52) U.S. Cl. CPC H10D 30/6728; H10B 12/315; H10B 12/482; H10B 12/488; H10D 30/6706; H10D 30/6735; H10D 30/6743; H10D 30/6755; H10W 20/435; H10B 12/05; H10B 12/50

(57) ABSTRACT

A semiconductor device includes a peripheral circuit area, and a cell array area arranged on the peripheral circuit area, wherein the cell array area includes bit lines extending in a first horizontal direction, active patterns extending in a vertical direction on the bit lines and each including a first side wall and a second side wall opposite to the first side wall, and a word line extending in a second horizontal direction on the bit lines, and including a first conductive layer arranged on the first side wall of each of the active patterns and extending in the second horizontal direction, and a second conductive layer including a first portion arranged on the second side wall of each of the active patterns and including a second portion arranged on a side wall of the first conductive layer, and cell capacitors respectively arranged on the active patterns.

### CROSS-REFERENCE TO RELATED APPLICATIONS

This present application claims priority to and the benefit under 35 U.S.C. § 119(a)-(d) of Korean Patent Application No. 10-2025-0045623, filed on Apr. 8, 2025, in the Korean Intellectual Property Office, the entire disclosure of which is incorporated herein by reference.

### FIELD

The disclosed concepts relate to a semiconductor device, and more specifically, to a semiconductor device including a vertical channel transistor.

### BACKGROUND

With the downscaling of semiconductor devices, the size of DRAM devices has also been decreased. In a DRAM device having a 1T-1C structure in which one capacitor is connected to one transistor, leakage current through a channel area may become increasingly larger as the DRAM device becomes smaller. To reduce leakage current, a vertical channel transistor including a channel area extending in a vertical direction has been proposed.

### SUMMARY

According to aspects of the disclosed concepts, there is provided a semiconductor device including a peripheral circuit area, and a cell array area arranged on the peripheral circuit area, wherein the cell array area includes a plurality of bit lines extending in a first horizontal direction, a plurality of active patterns extending in a vertical direction on the plurality of bit lines and each including a first side wall and a second side wall opposite to the first side wall, a word line extending in a second horizontal direction crossing the first horizontal direction on the plurality of bit lines, and including a first conductive layer arranged on the first side wall of each of the plurality of active patterns and extending in the second horizontal direction, and a second conductive layer including a first portion arranged on the second side wall of each of the plurality of active patterns and including a second portion arranged on a side wall of the first conductive layer, and a plurality of cell capacitors respectively arranged on the plurality of active patterns.

According to aspects of the disclosed concepts, there is provided a semiconductor device including a plurality of bit lines arranged on a substrate and extending in a first horizontal direction, a plurality of active patterns extending in a vertical direction on the plurality of bit lines and each including a first side wall and a second side wall, which are opposite to each other, and a third side wall and a fourth side wall, which are opposite to each other, a word line extending in a second horizontal direction crossing the first horizontal direction on the plurality of bit lines, and including a first conductive layer arranged on the first side wall of each of the plurality of active patterns and extending in the second horizontal direction, and a second conductive layer including a first portion arranged on the second side wall, the third side wall, and the fourth side wall of each of the plurality of active patterns and extending in the second horizontal direction, and a cell capacitor arranged on each of the plurality of active patterns.

According to aspects of the disclosed concepts, there is provided a semiconductor device including a peripheral circuit area, and a cell array area arranged on the peripheral circuit area, wherein the cell array area includes a plurality of bit lines extending in a first horizontal direction, a plurality of active patterns extending in a vertical direction on the plurality of bit lines and each including a first side wall and a second side wall opposite to the first side wall, a word line extending in a second horizontal direction crossing the first horizontal direction on the plurality of bit lines, and including a first conductive layer arranged on the first side wall of each of the plurality of active patterns and extending in the second horizontal direction, and a second conductive layer including a first portion arranged on the second side wall of each of the plurality of active patterns and a second portion arranged on a side wall of the first conductive layer, the second conductive layer extending in the second horizontal direction, a plurality of gate insulating layer structures arranged between the word line and each of the plurality of active patterns and including a first gate insulating layer arranged between the first side wall of each of the plurality of active patterns and the first conductive layer, and a second gate insulating layer arranged between the second side wall of each of the plurality of active patterns and the first portion of the second conductive layer, and a plurality of cell capacitors respectively arranged on the plurality of active patterns.

### BRIEF DESCRIPTION OF THE DRAWINGS

Embodiments will be more clearly understood from the following detailed description taken in conjunction with the accompanying drawings in which:

FIG. 1 is a schematic view showing a semiconductor device according to some embodiments;

FIG. 2 is a perspective view schematically showing a partial configuration of FIG. 1;

FIG. 3 is a layout diagram of a portion II of FIG. 1;

FIG. 4 is a cross-sectional view taken along a line A1-A1′ of FIG. 3;

FIG. 5 is a cross-sectional view taken along a line A2-A2′ of FIG. 3;

FIG. 6 is a cross-sectional view taken along a line A3-A3′ of FIG. 3;

FIG. 7 is an enlarged view of a portion EN1 of FIG. 4;

FIG. 8 is a plan view at a first vertical level of FIG. 7;

FIGS. 9 and 10 are cross-sectional views showing a semiconductor device according to some embodiments;

FIG. 11 is an enlarged view of a portion EN1 of FIG. 9;

FIGS. 12 and 13 are cross-sectional views showing a semiconductor device according to some embodiments;

FIG. 14 is an enlarged view of a portion EN1 of FIG. 12;

FIG. 15 is a cross-sectional view showing a semiconductor device according to some embodiments;

FIG. 16 is a plan view showing a semiconductor device according to some embodiments;

FIGS. 17 to 33 are schematic views showing a method of manufacturing a semiconductor device, according to some embodiments; FIGS. 18A, 19A, 20, 21A, 22A, 23A, 24A, 25A, 26A, 27A, 28A, 29A, 31, 32, and 33 are cross-sectional views taken along the line A1-A1′ of FIG. 3; FIGS. 26B and 27B are cross-sectional views taken along the line A2-A2′ of FIG. 3; FIGS. 17, 18B, 22B, 23B, 24B, 25B, 29B, and 30 are cross-sectional views taken along the line A3-A3′ of FIG. 3; and FIGS. 19B, 21B, 23C, 24C, 25C, and 28B are each a plan view at a first vertical level of FIG. 19A.

### DETAILED DESCRIPTION

The disclosed concepts provide a semiconductor device with excellent electrical performance.

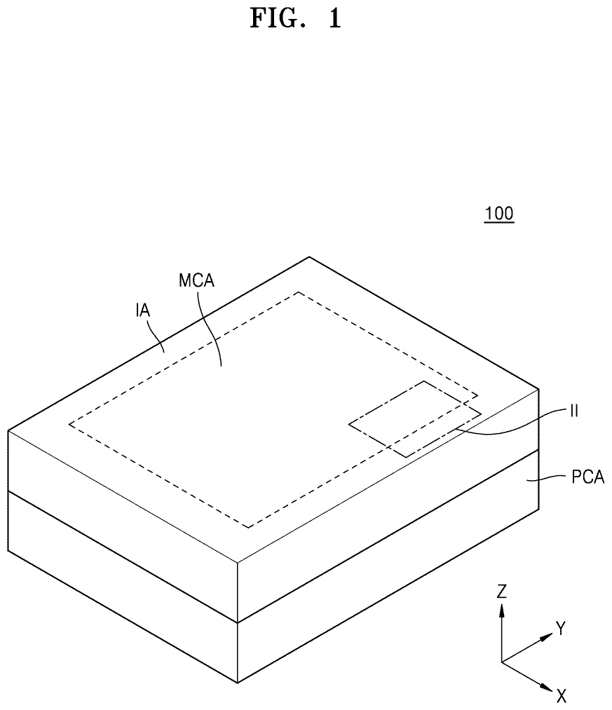

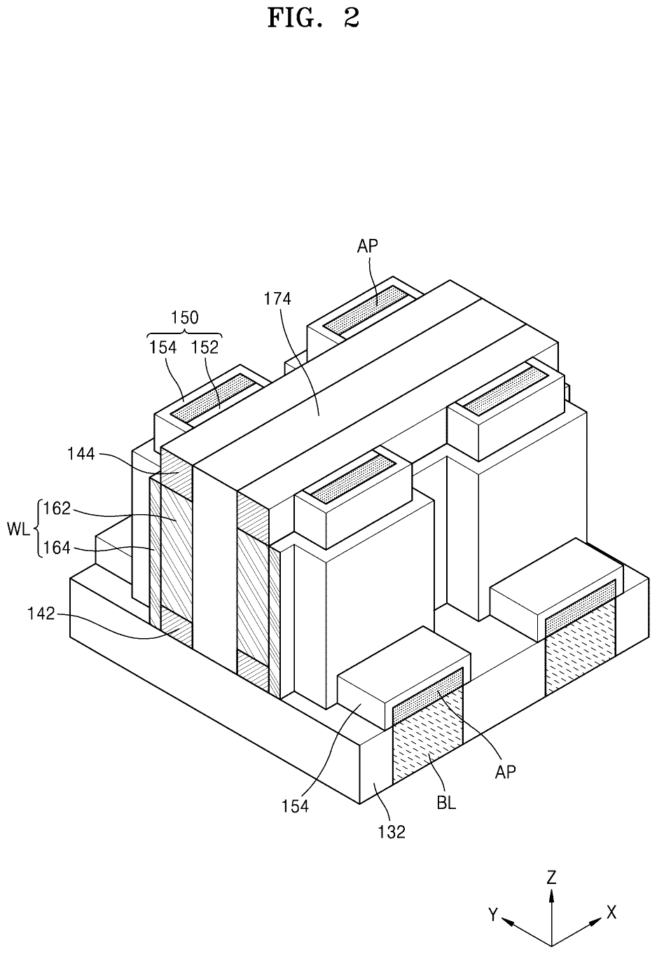

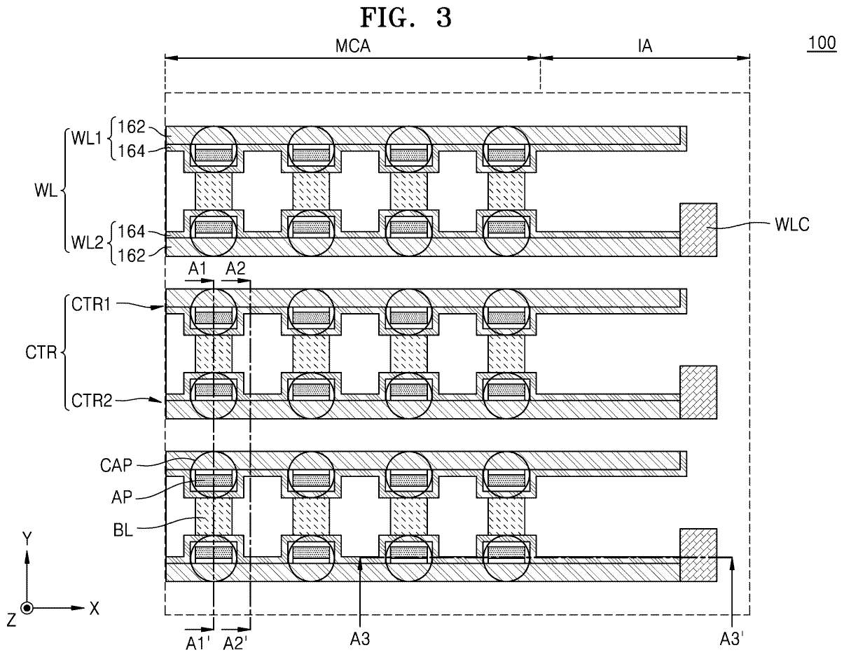

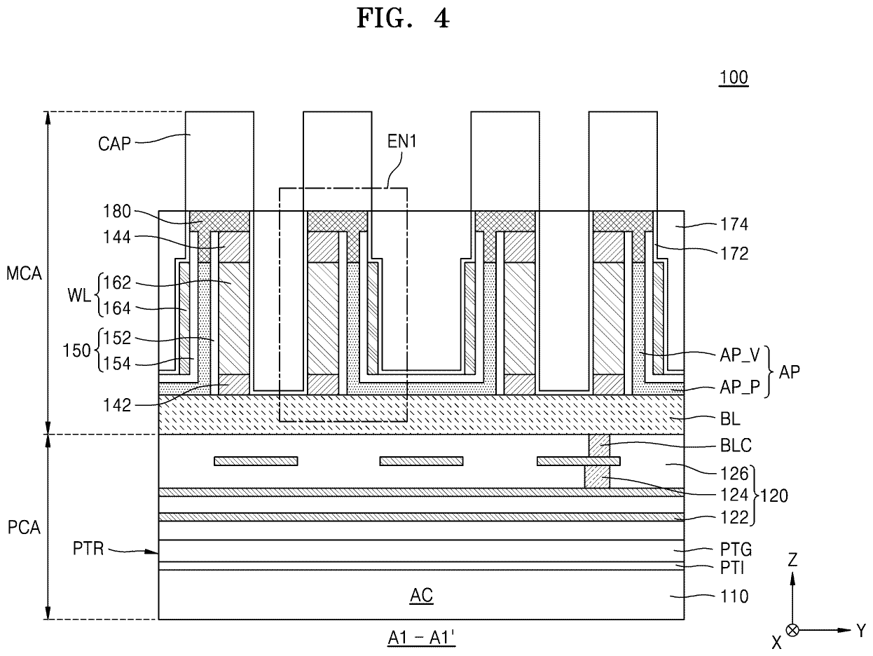

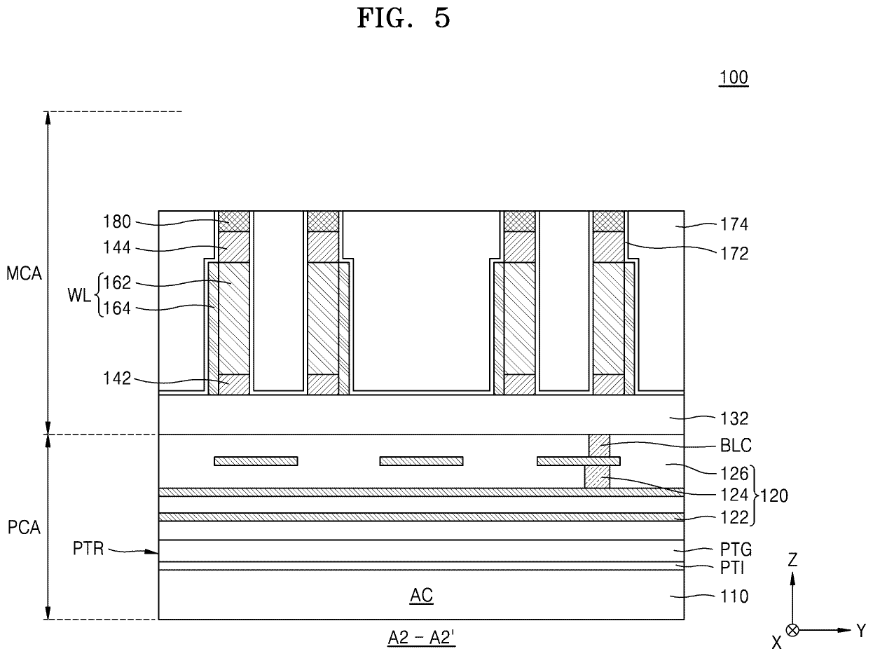

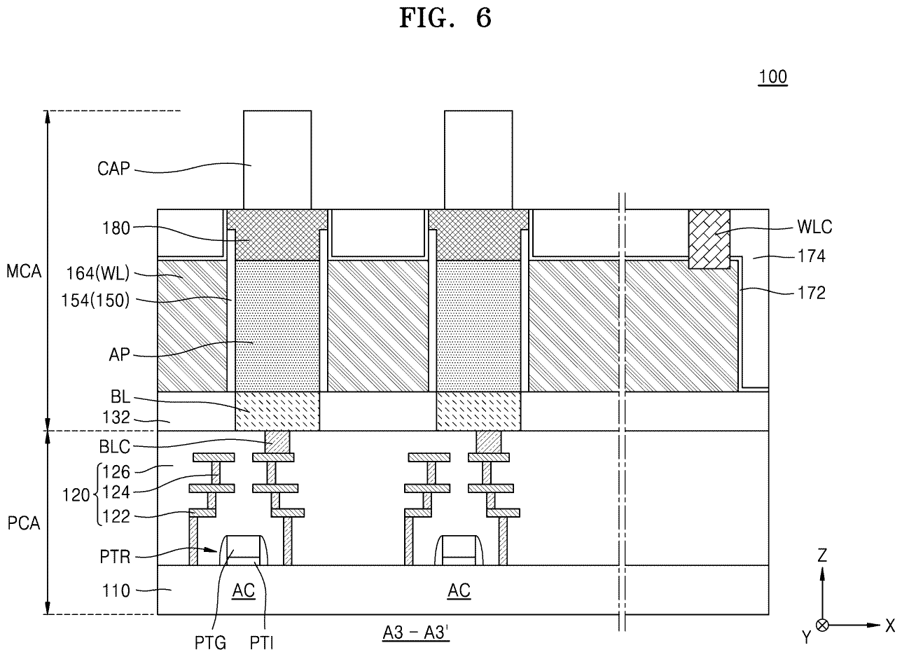

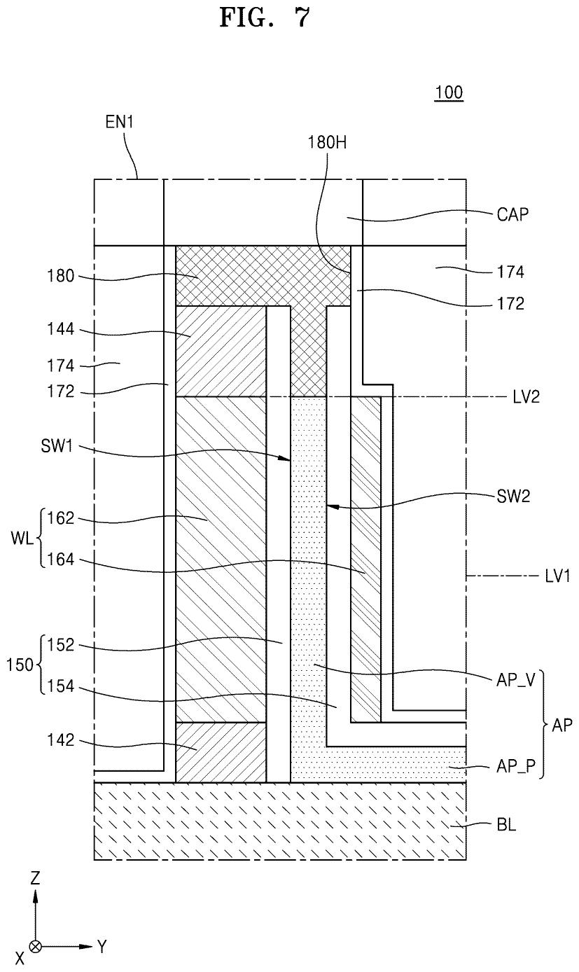

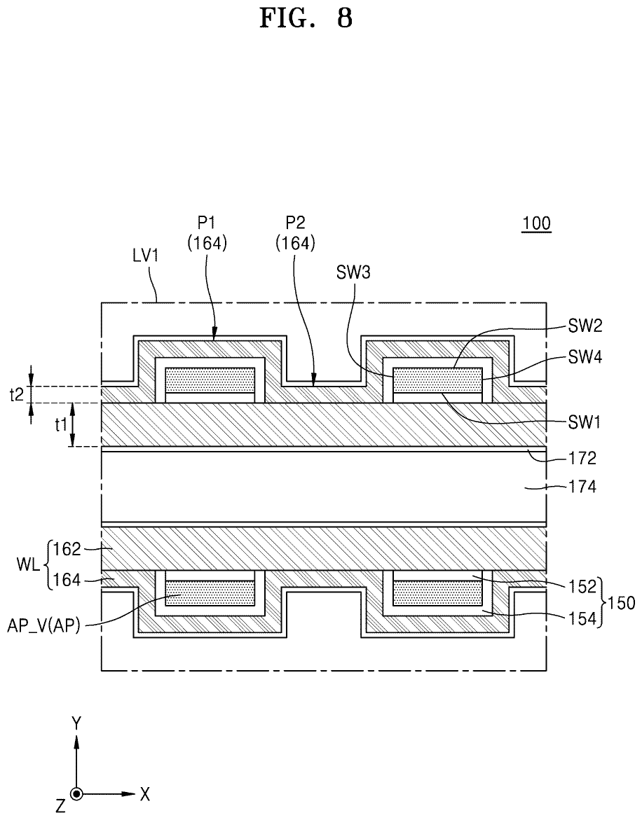

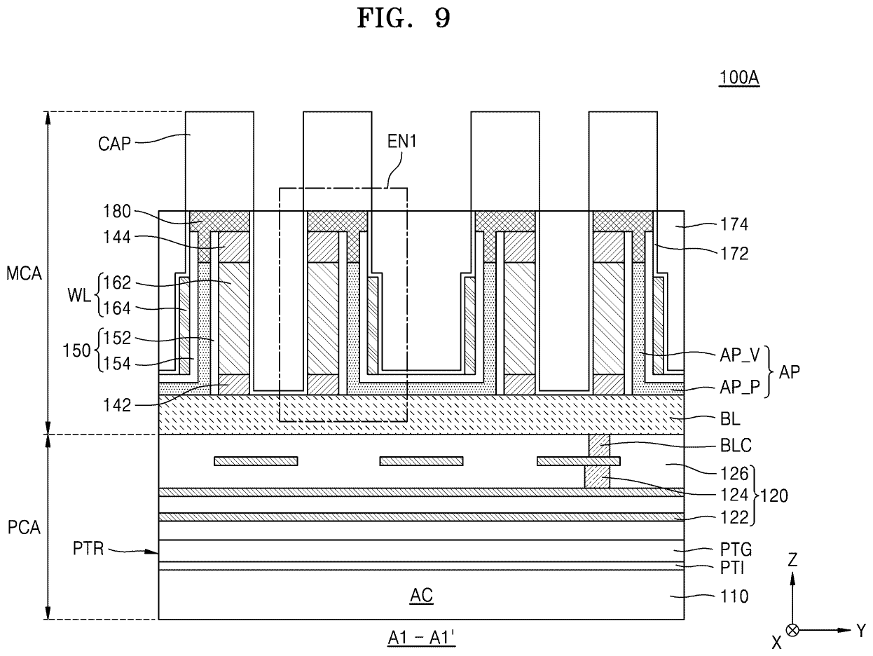

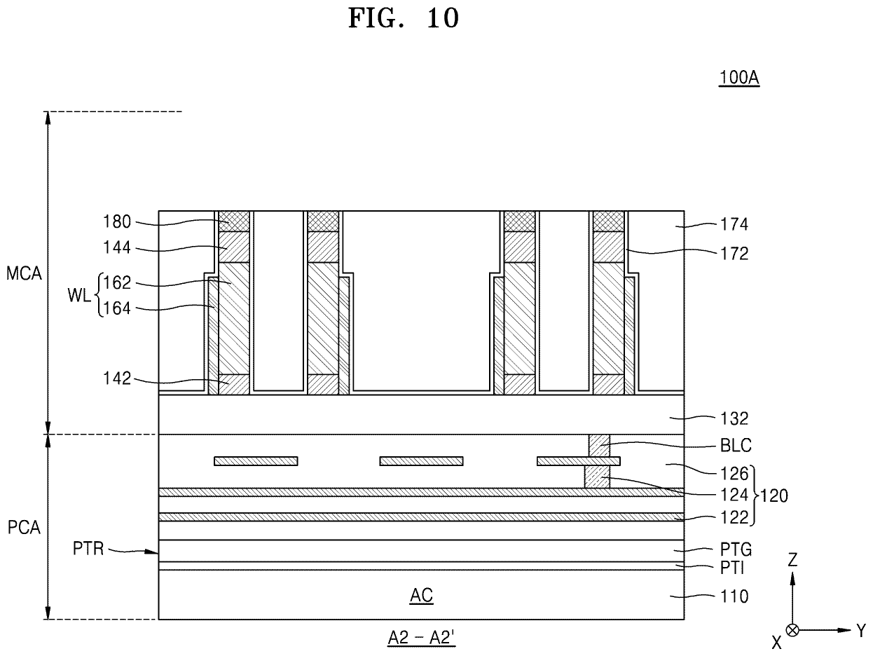

FIG. 1 is a schematic view showing a semiconductor device 100 according to some embodiments. FIG. 2 is a perspective view schematically showing a partial configuration of FIG. 1. FIG. 3 is a layout diagram of a portion II of FIG. 1. FIG. 4 is a cross-sectional view taken along a line A1-A1′ of FIG. 3. FIG. 5 is a cross-sectional view taken along a line A2-A2′ of FIG. 3. FIG. 6 is a cross-sectional view taken along a line A3-A3′ of FIG. 3. FIG. 7 is an enlarged view of a portion EN1 of FIG. 4. FIG. 8 is a plan view at a first vertical level LV1 of FIG. 7.

Referring to FIGS. 1 to 8, the semiconductor device 100 may include a cell array area MCA and a peripheral circuit area PCA, which are arranged at different vertical levels from each other. The peripheral circuit area PCA and the cell array area MCA may overlap each other in a vertical direction. For example, as shown in FIG. 1, the cell array area MCA may be arranged on the peripheral circuit area PCA, and the semiconductor device 100 may have a cell over periphery (COP) structure. An interface area IA may be arranged on at least one side of the cell array area MCA. In some embodiments, the cell array area MCA may be surrounded by the interface area IA in a plan view.

In some embodiments, the cell array area MCA may be a memory cell area of a DRAM device, and the peripheral circuit area PCA may be a core area or a peripheral circuit area of a DRAM device. For example, the peripheral circuit area PCA may include a peripheral circuit transistor PTR (see FIG. 4) for transmitting a signal and/or power to a memory cell array included in the cell array area MCA. In some embodiments, the peripheral circuit transistor PTR may include various circuits such as a command decoder, control logic, an address buffer, a row decoder, a column decoder, a sense amplifier, and a data input/output circuit.

As shown in FIGS. 2 and 3, a plurality of word lines WL may extend in a first horizontal direction X in the cell array area MCA. In addition, a plurality of bit lines BL may extend in a second horizontal direction Y. A plurality of cell transistors CTR may be arranged at intersecting points of the plurality of word lines WL and the plurality of bit lines BL. A plurality of cell capacitors CAP may be respectively arranged on the plurality of cell transistors CTR.

The plurality of word lines WL may include a first word line WL1 and a second word line WL2, which are alternately arranged in the second horizontal direction Y, and the plurality of cell transistors CTR may include a first cell transistor CTR1 and a second cell transistor CTR2, which are alternately arranged in the second horizontal direction Y. The first cell transistor CTR1 may be arranged adjacent to the first word line WL1, and the second cell transistor CTR2 may be arranged adjacent to the second word line WL2. The first cell transistor CTR1 and the second cell transistor CTR2 may be mirror symmetrical to each other. For example, the first cell transistor CTR1 and the second cell transistor CTR2 may be mirror symmetrical about a central line extending in the first horizontal direction X and arranged between the first cell transistor CTR1 and the second cell transistor CTR2.

The interface area IA may be an area where contacts, vias, wiring, etc. are formed for electrical connection between the memory cell array included in the cell array area MCA and the peripheral circuit transistor PTR included in the peripheral circuit area PCA. For example, a word line WL may extend from the cell array area MCA to the interface area IA, and a word line contact WLC may be arranged in the interface area IA and be connected to the word line WL.

In some embodiments, the peripheral circuit area PCA may include a substrate 110 and the peripheral circuit transistor PTR arranged on the substrate 110.

In some embodiments, the substrate 110 may include silicon, for example, single crystalline silicon, polycrystalline silicon, or amorphous silicon. In some embodiments, the substrate 110 may include at least one selected from Ge, SiGe, SiC, GaAs, InAs, or InP. An active area AC may be defined within the substrate 110.

In some embodiments, the peripheral circuit transistor PTR may be arranged on the active area AC of the substrate 110. The peripheral circuit transistor PTR may include at least one of a planar transistor, a FinFET transistor, a multi-bridge channel transistor, and a buried channel array transistor. In some embodiments, the peripheral circuit transistor PTR may include a gate electrode PTG and a gate insulating layer PTI. A source area and a drain area may be respectively arranged in upper portions of the substrate at both sides of the gate electrode PTG.

The peripheral circuit transistor PTR may be configured to apply a driving signal or a driving voltage to at least one of a bit line BL and the word line WL, which are arranged in the cell array area MCA vertically overlapping the peripheral circuit area PCA.

A peripheral circuit wiring structure 120 may be arranged on the substrate 110. The peripheral circuit wiring structure 120 may include a peripheral circuit wiring 122, a peripheral circuit contact 124, and a peripheral circuit insulating layer 126. The peripheral circuit wiring 122 and the peripheral circuit contact 124 may be electrically connected to the peripheral circuit transistor PTR and/or the substrate 110, and the peripheral circuit insulating layer 126 may cover the peripheral circuit transistor PTR, the peripheral circuit wiring 122, and the peripheral circuit contact 124, on the substrate 110. The peripheral circuit insulating layer 126 may include an oxide film, a nitride film, a low dielectric film, or a combination thereof, and may be formed to have a stacked structure of a plurality of insulating layers.

The cell array area MCA may be arranged on the peripheral circuit wiring structure 120. In the cell array area MCA, the plurality of bit lines BL, the plurality of cell transistors CTR, and a cell capacitor CAP may be sequentially arranged in a vertical direction Z. For example, the plurality of bit lines BL may be arranged on the peripheral circuit wiring structure 120, a cell transistor CTR may be arranged on the plurality of bit lines BL, and the cell capacitor CAP may be arranged on the cell transistor CTR. In some embodiments, the bit line BL may be arranged closer to a top surface of the substrate 110 than the cell transistor CTR or the cell capacitor CAP. Accordingly, a vertical distance between the bit line BL and the peripheral circuit transistor PTR may be less than a vertical distance between the cell capacitor CAP and the peripheral circuit transistor PTR.

In some embodiments, the plurality of bit lines BL may extend in the second horizontal direction Y. The bit line BL may include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof. A first insulating layer 132 may be arranged between the plurality of bit lines BL. The first insulating layer 132 may fill a space between the plurality of bit lines BL, and may have a plurality of line pattern shapes extending in the second horizontal direction Y between the plurality of bit lines BL.

In some embodiments, a bit line contact BLC may be arranged between a bottom surface of the bit line BL and the peripheral circuit wiring 122. The bit line BL may be electrically connected to the peripheral circuit transistor PTR by the bit line contact BLC.

The plurality of cell transistors CTR may be arranged on the plurality of bit lines BL. The plurality of cell transistors CTR may include a plurality of active patterns AP, a plurality of gate insulating layer structures 150, and the plurality of word lines WL. The plurality of cell transistors CTR may include gate-all-around (GAA)-type transistors.

In some embodiments, the plurality of active patterns AP may be spaced apart from each other in the first horizontal direction X and the second horizontal direction Y and may be arranged in the form of a matrix. Each of the plurality of active patterns AP may include a vertical extension portion AP_V and a horizontal extension portion AP_P. The horizontal extension portion AP_P of each of the plurality of active patterns AP may be arranged on a top surface of the bit line BL.

In some embodiments, each of the plurality of active patterns AP may have a U-shaped vertical cross-section. For example, each of the plurality of active patterns AP may have a shape in which bottom portions of two vertical extension portions AP_V are respectively connected to opposite ends of one horizontal extension portion AP_P arranged therebetween. One of the two vertical extension portions AP_V may be a channel area of the first cell transistor CTR1, and the other of the two vertical extension portions AP_V may be a channel area of the second cell transistor CTR2.

In some embodiments, the plurality of active patterns AP may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), magnesium aluminum zinc oxide (MgₓAl_{y}Zn_{z}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), or silicon.

As shown in FIG. 8, the vertical extension portion AP_V of each of the plurality of active patterns AP may include a first side wall SW1, a second side wall SW2, a third side wall SW3, and a fourth side wall SW4. The first side wall SW1 and the second side wall SW2 may be arranged opposite to each other and may extend in the first horizontal direction X. The third side wall SW3 may be arranged to meet or to be connected to the first side wall SW1 and the second side wall SW2 and may extend in the second horizontal direction Y. The fourth side wall SW4 may be arranged to meet or to be connected to the first side wall SW1 and the second side wall SW2 and may be arranged opposite to the third side wall SW3.

In some embodiments, as shown in FIG. 8, the third side wall SW3 and the fourth side wall SW4 may have flat side wall profiles and may be arranged orthogonal to the first side wall SW1 and the second side wall SW2. However, in some embodiments, due to tolerances or the like in a manufacturing process, at least one of the third side wall SW3 and the fourth side wall SW4 may have a rounded profile and may be connected to at least one of the first side wall SW1 and the second side wall SW2 at an inclined angle.

A gate insulating layer structure 150 may be arranged on the side walls of each of the plurality of active patterns AP. The gate insulating layer structure 150 may include a first gate insulating layer 152 and a second gate insulating layer 154. The first gate insulating layer 152 may be arranged on the first side wall SW1 of the vertical extension portion AP_V of the plurality of active patterns AP and may extend in the vertical direction Z. The second gate insulating layer 154 may be arranged on the second side wall SW2, the third side wall SW3, and the fourth side wall SW4 of the vertical extension portion AP_V of each of the plurality of active patterns AP and may extend in the vertical direction Z. A portion of the second gate insulating layer 154 may be arranged on the horizontal extension portion AP_P of each of the plurality of active patterns AP.

The first gate insulating layer 152 may have a width in the first horizontal direction X that is substantially the same as the width of the vertical extension portion AP_V of each of the plurality of active patterns AP in the first horizontal direction X. The second gate insulating layer 154 may be arranged on the second side wall SW2, the third side wall SW3, and the fourth side wall SW4 of the vertical extension portion AP_V, and may be in contact with opposite side surfaces of the first gate insulating layer 152. Accordingly, as shown in FIG. 8, in a plan view, the first gate insulating layer 152 and the second gate insulating layer 154 may collectively surround the vertical extension portion AP_V.

In some embodiments, the first gate insulating layer 152 and the second gate insulating layer 154 may include at least one of silicon oxide, silicon nitride, or a high-k metal oxide.

In some embodiments, the first gate insulating layer 152 and the second gate insulating layer 154 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanate (BaSrTiO), barium titanate (BaTiO), lead zirconium titanate (PbZrTiO), strontium tantalum bismuth oxide (SrTaBiO), bismuth ferrite (BiFeO), strontium titanate (SrTiO), yttrium oxide (YO), aluminum oxide (AlO), or lead scandium tantalum oxide (PbScTaO).

In some embodiments, the plurality of word lines WL may surround the vertical extension portion AP_V of each of the plurality of active patterns AP and may extend in the first horizontal direction X. Each of the vertical extension portions AP_V may be surrounded by the gate insulating layer structure 150 so that the gate insulating layer structure 150 is arranged between the word line WL and each of the vertical extension portions AP_V.

In some embodiments, each of the plurality of word lines WL may include a first conductive layer 162 and a second conductive layer 164.

In some embodiments, the first conductive layer 162 may have a line pattern shape extending in the first horizontal direction X. The first conductive layer 162 may have a side wall extending straight in the first horizontal direction X. In some embodiments, the first side wall SW1 of the vertical extension portion AP_V of each of the plurality of active patterns AP may be arranged on the side wall of the first conductive layer 162, and the first gate insulating layer 152 may be arranged between the side wall of the first conductive layer 162 and the first side wall SW1 of the vertical extension portion AP_V.

In some embodiments, the second conductive layer 164 may include a first portion P1 and a second portion P2 and may extend in the first horizontal direction X. The first portion P1 of the second conductive layer 164 may be arranged on the second side wall SW2, the third side wall SW3, and the fourth side wall SW4 of the vertical extension portion AP_V of each of the plurality of active patterns AP. The vertical extension portion AP_V of each of the plurality of active patterns AP may be arranged between the first portion P1 of the second conductive layer 164 and the first conductive layer 162. The second portion P2 of the second conductive layer 164 may be arranged on a side wall of the first conductive layer 162. The second portion P2 of the second conductive layer 164 may be in direct contact with the side wall of the first conductive layer 162.

In some embodiments, the first gate insulating layer 152 may be arranged between the first conductive layer 162 and the first side wall SW1 of the vertical extension portion AP_V of each of the plurality of active patterns AP, and the second gate insulating layer 154 may be arranged between the first portion P1 of the second conductive layer 164 and the second side wall SW2, the third side wall SW3, and the fourth side wall SW4 of the vertical extension portion AP_V of each of the plurality of active patterns AP.

In some embodiments, in a plan view, the word line WL may surround the vertical extension portion AP_V of each of the plurality of active patterns AP and may extend in the first horizontal direction X. As the first conductive layer 162 and the second conductive layer 164 are arranged to surround the first side wall SW1, the second side wall SW2, the third side wall SW3, and the fourth side wall SW4 of the vertical extension portion AP_V of each of the plurality of active patterns AP, the word line WL may be a GAA-type gate electrode.

In some embodiments, a top surface of the first conductive layer 162 may be arranged at a second vertical level LV2, and a top surface of the second conductive layer 164 may be arranged at a second vertical level LV2. In other words, the top surface of the first conductive layer 162 may be coplanar with the top surface of the second conductive layer 164. In some embodiments, the top surfaces of the first conductive layer 162 and the second conductive layer 164 may be arranged at a vertical level that is lower than a top surface of the gate insulating layer structure 150.

In some embodiments, as shown in FIG. 8, the first conductive layer 162 may have a first thickness t1 in the second horizontal direction Y, and the second conductive layer 164 may have a second thickness t2 in the second horizontal direction Y. In some embodiments, the second thickness t2 may be different from the first thickness t1. For example, although FIG. 8 illustrates, as an example, that the second thickness t2 is less than the first thickness t1, the second thickness t2 may be greater than or equal to the first thickness t1.

In some embodiments, the first conductive layer 162 and the second conductive layer 164 may include Ti, TiN, Ta, TaN, Mo, Ru, W, WN, TiSiN, WSiN, polysilicon, or a combination thereof. In some embodiments, the first conductive layer 162 may include the same material as the second conductive layer 164. In some embodiment, the first conductive layer 162 may include a different material from the second conductive layer 164. Although FIG. 8 shows, as an example, that each of the first conductive layer 162 and the second conductive layer 164 is formed as a single layer, in some embodiments, each of the first conductive layer 162 and the second conductive layer 164 may be formed to have a multilayer structure including two or more material layers.

In some embodiments, a lower mold layer 142 may be arranged between a bottom surface of the first conductive layer 162 and the bit line BL and between the bottom surface of the first conductive layer 162 and the first insulating layer 132. Opposite side walls of the lower mold layer 142 may be aligned with opposite side walls of the first conductive layer 162, and the lower mold layer 142 may extend in the first horizontal direction X.

In some embodiments, an upper mold layer 144 may be arranged on a top surface of the first conductive layer 162. Opposite side walls of the upper mold layer 144 may be aligned with the opposite side walls of the first conductive layer 162, and the upper mold layer 144 may extend in the first horizontal direction X.

In some embodiments, the lower mold layer 142 and the upper mold layer 144 may include at least one of silicon oxide, silicon nitride, silicon oxynitride, or a low-k dielectric material.

An insulating liner 172 and a buried insulating layer 174 may be arranged on a side wall of the first conductive layer 162 and a side wall of the second conductive layer 164. The insulating liner 172 may be conformally arranged on a side wall of the first conductive layer 162, a side wall and top surface of the second conductive layer 164, and a side wall and top surface of the gate insulating layer structure 150. The buried insulating layer 174 may be arranged on the insulating liner 172 to fill a space between two adjacent first conductive layers 162 and a space between two adjacent second conductive layers 164.

In some embodiments, in the cell array area MCA, the first word line WL1 and the second word line WL2 may be mirror symmetrical to each other and may extend in the first horizontal direction X. In the interface area IA, the first word line WL1 and the second word line WL2 may extend in the first horizontal direction X, and the word line contact WLC may be arranged on at least one of the first word line WL1 and the second word line WL2.

A plurality of landing pads 180 may be respectively arranged on the plurality of cell transistors CTR. Each of the plurality of landing pads 180 may be arranged within a landing pad opening 180H. A bottom surface of a landing pad 180 may be in contact with a top surface of the vertical extension portion AP_V of each of the plurality of active patterns AP, and a portion of an upper side of the landing pad 180 may be arranged on a top surface of the gate insulating layer structure 150 and a top surface of the upper mold layer 144. The plurality of landing pads 180 may include Ti, TiN, Ta, TaN, W, WN, TiSiN, WSiN, polysilicon, or a combination thereof.

The cell capacitor CAP may be arranged on each of the plurality of landing pads 180. The cell capacitor CAP may have a metal-insulator-metal type capacitor structure. For example, the cell capacitor CAP may include a first electrode, a second electrode, and a capacitor dielectric layer arranged between the first electrode and the second electrode.

In some embodiments, instead of the cell capacitor CAP, a memory element such as a variable resistance memory element, a phase change memory element, or a magnetic memory element may be arranged.

In some embodiments, the word line WL may include the first conductive layer 162 and the second conductive layer 164, and may be a GAA-type gate electrode arranged to surround all four side walls of each of the plurality of active patterns AP. As the semiconductor device 100 includes a GAA-type cell transistor, electrical performance of the cell transistor may be improved, for example, by a decrease in leakage current of the cell transistor and an increase in cell operating current.

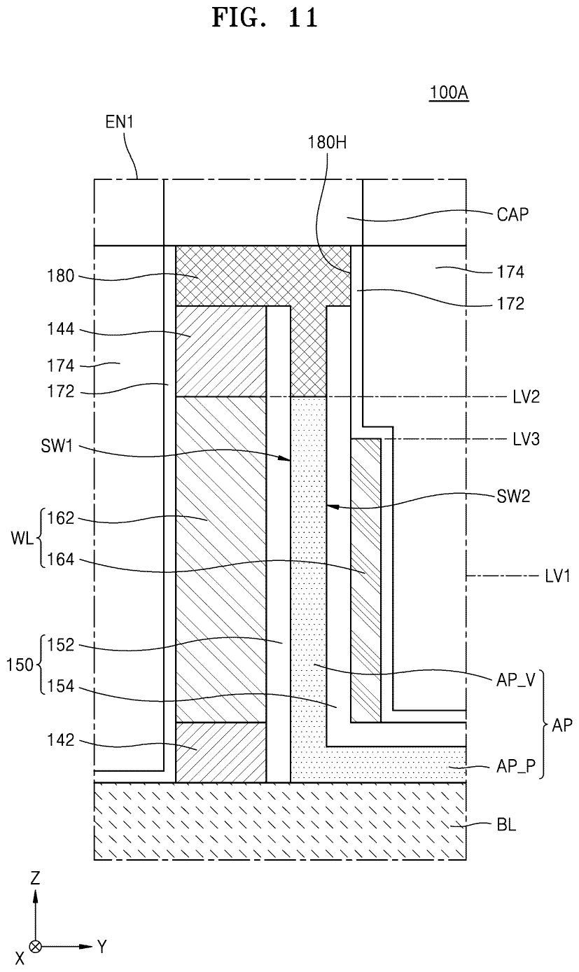

FIGS. 9 and 10 are cross-sectional views showing a semiconductor device 100A according to some embodiments. FIG. 11 is an enlarged view of a portion EN1 of FIG. 9.

Referring to FIGS. 9 to 11, a top surface of the first conductive layer 162 may be arranged at the second vertical level LV2, and a top surface of the second conductive layer 164 may be arranged at a third vertical level LV3 that is lower than the second vertical level LV2. As shown in FIG. 10, as the top surface of the second conductive layer 164 is arranged lower than the top surface of the first conductive layer 162, a portion of a side wall of the first conductive layer 162 arranged at a vertical level that is higher than the top surface of the second conductive layer 164 may be covered by the insulating liner 172. In addition, a bottom surface of the landing pad 180 and the top surface of the second conductive layer 164 may be spaced apart from each other in the vertical direction Z.

In a manufacturing method according to some embodiments, an active pattern AP may be formed on a side wall of the first conductive layer 162, and then the second conductive layer 164 may be formed on a side wall of the active pattern AP. After forming the second conductive layer 164, a recess process for reducing the height of a top surface of the second conductive layer 164 may be performed, and in some embodiments, the height of the second conductive layer 164 may be reduced so that the top surface of the second conductive layer 164 is arranged at a vertical level that is lower than a top surface of the first conductive layer 162.

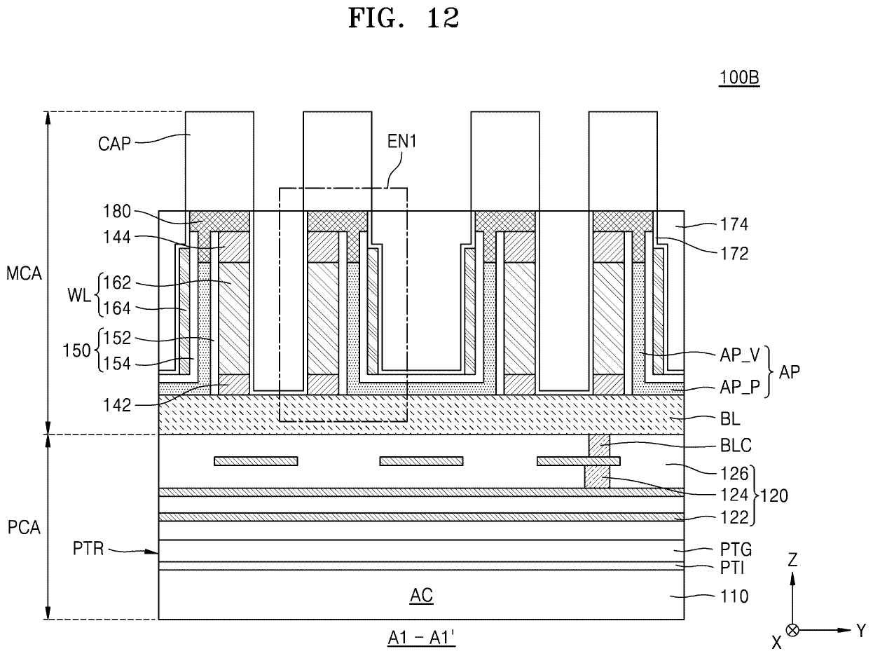

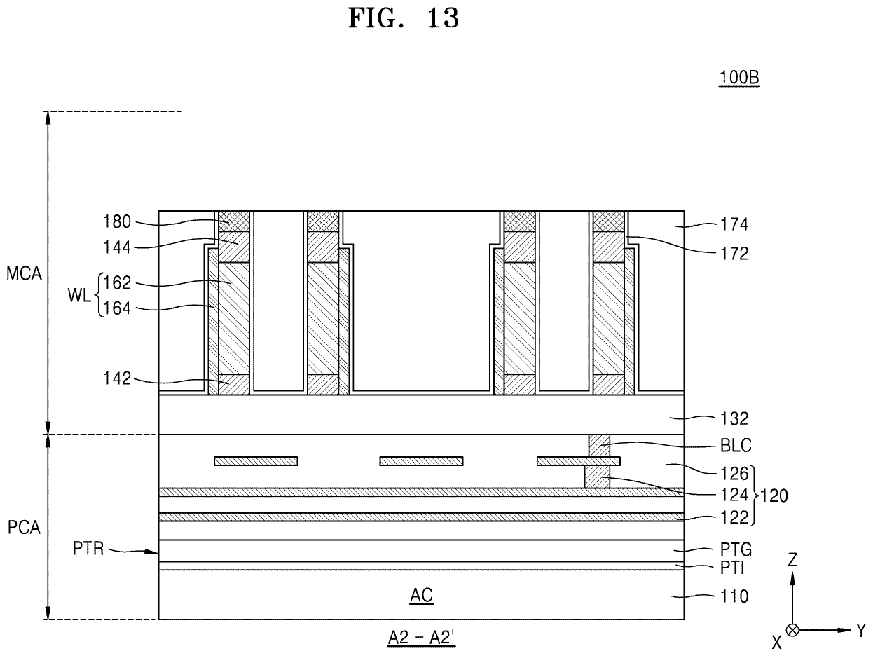

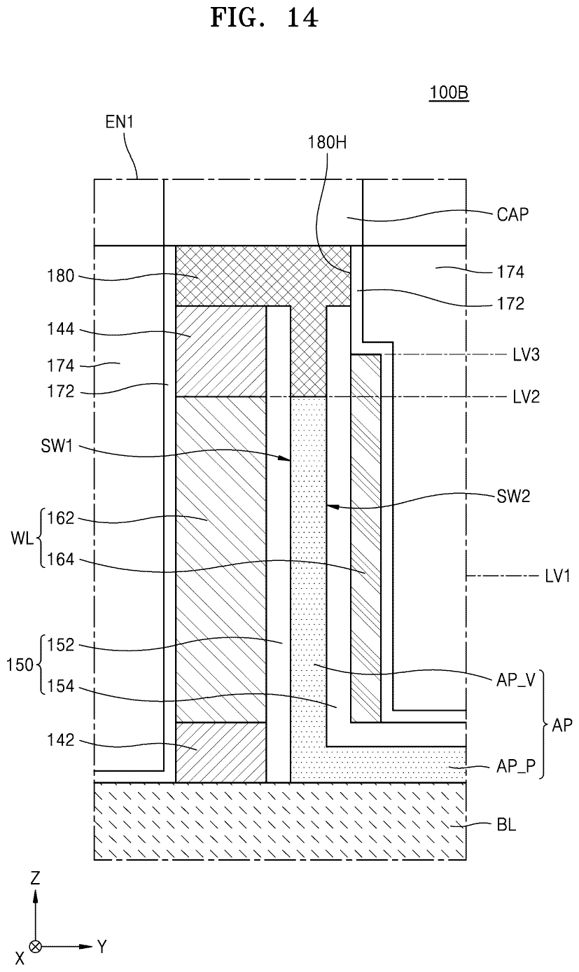

FIGS. 12 and 13 are cross-sectional views showing a semiconductor device 100B according to some embodiments. FIG. 14 is an enlarged view of a portion EN1 of FIG. 12.

Referring to FIGS. 12 to 14, a top surface of the first conductive layer 162 may be arranged at the second vertical level LV2, and a top surface of the second conductive layer 164 may be arranged at the third vertical level LV3 that is higher than the second vertical level LV2. As shown in FIG. 13, as the top surface of the second conductive layer 164 is arranged higher than the top surface of the first conductive layer 162, an upper side of a side wall of the second conductive layer 164 arranged at a vertical level that is higher than the top surface of the first conductive layer 162 may be in contact with a side wall of the upper mold layer 144.

In a manufacturing method according to some embodiments, the active pattern AP may be formed on a side wall of the first conductive layer 162, and then the second conductive layer 164 may be formed on a side wall of the active pattern AP. After forming the second conductive layer 164, a recess process for reducing the height of a top surface of the second conductive layer 164 may be performed, and in some embodiments, the second conductive layer 164 may be formed so that the top surface of the second conductive layer 164 is arranged at a vertical level that is higher than a top surface of the first conductive layer 162.

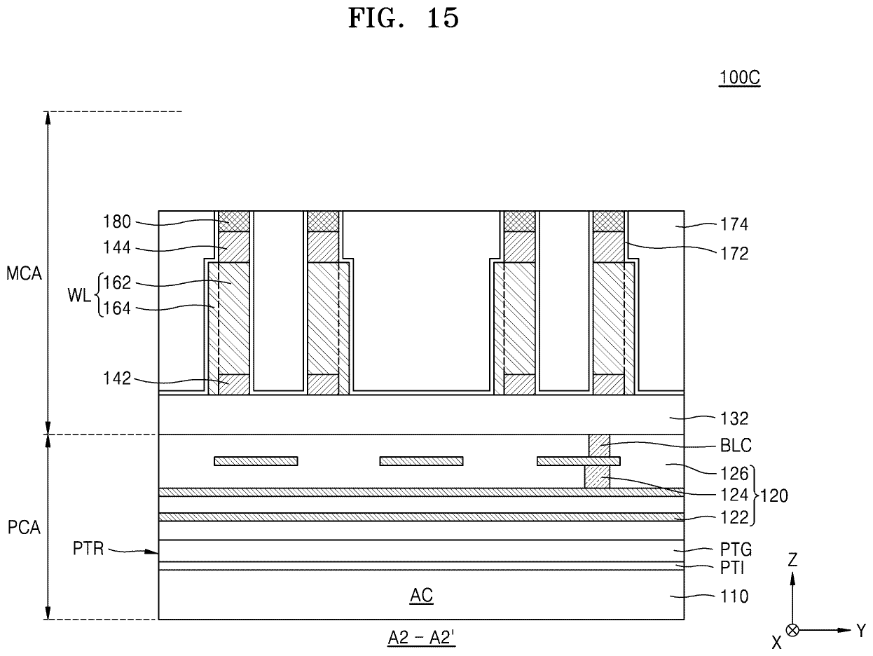

FIG. 15 is a cross-sectional view showing a semiconductor device 100C according to some embodiments.

Referring to FIG. 15, the word line WL may include the first conductive layer 162 and the second conductive layer 164, and the first conductive layer 162 and the second conductive layer 164 may include the same material. In some embodiments, a boundary between the first conductive layer 162 and the second conductive layer 164 may be visually indistinguishable.

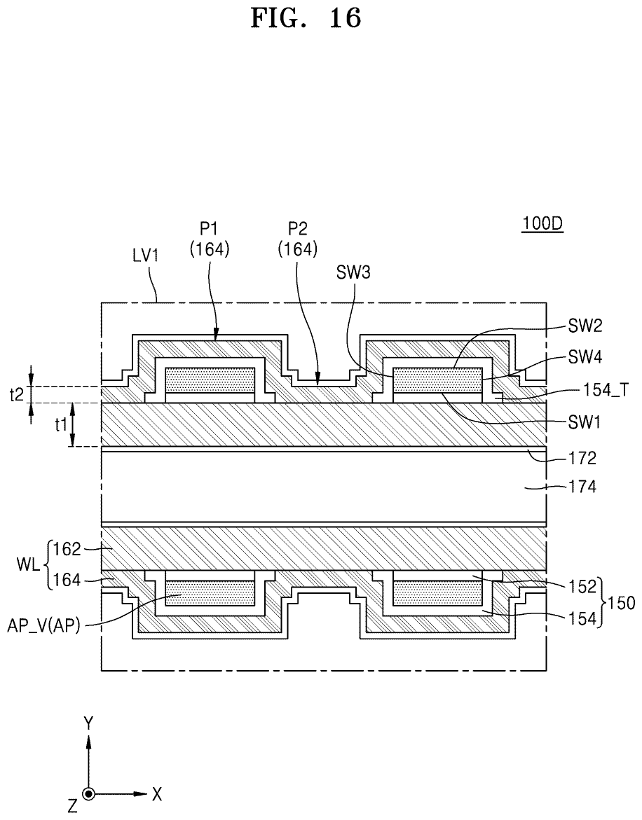

FIG. 16 is a plan view showing a semiconductor device 100D according to some embodiments.

Referring to FIG. 16, the second gate insulating layer 154 may be arranged on the second side wall SW2, the third side wall SW3, and the fourth side wall SW4 of the vertical extension portion AP_V of the active pattern AP, and a portion of the second gate insulating layer 154 may extend onto a side wall of the first conductive layer 162. The portion of the second gate insulating layer 154 extending onto the side wall of the first conductive layer 162 may be referred to as a tail portion 154_T. The tail portion 154_T may be arranged adjacent to at least one of the third side wall SW3 and the fourth side wall SW4 of the vertical extension portion AP_V.

In some embodiments, even when misalignment of a mask pattern occurs or process tolerances are exceeded during an etching process on the second gate insulating layer 154, unwanted electrical connection or bridge failure between the active pattern AP and the second conductive layer 164 may be prevented.

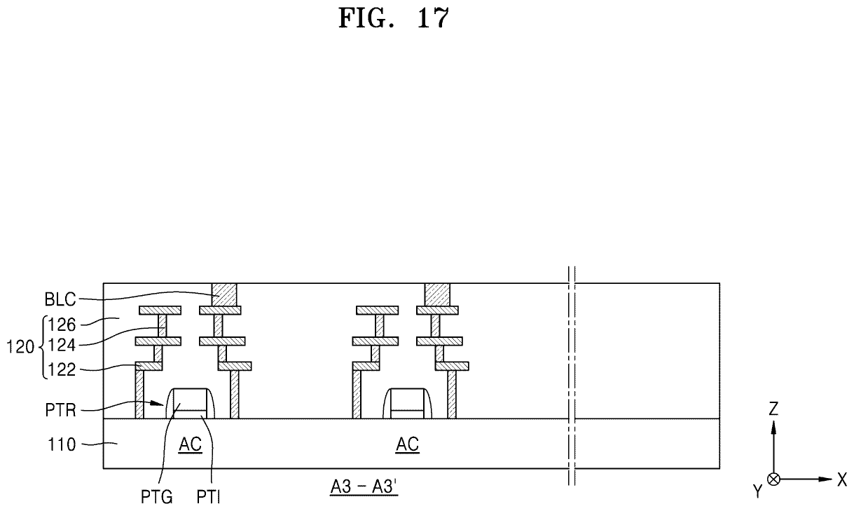

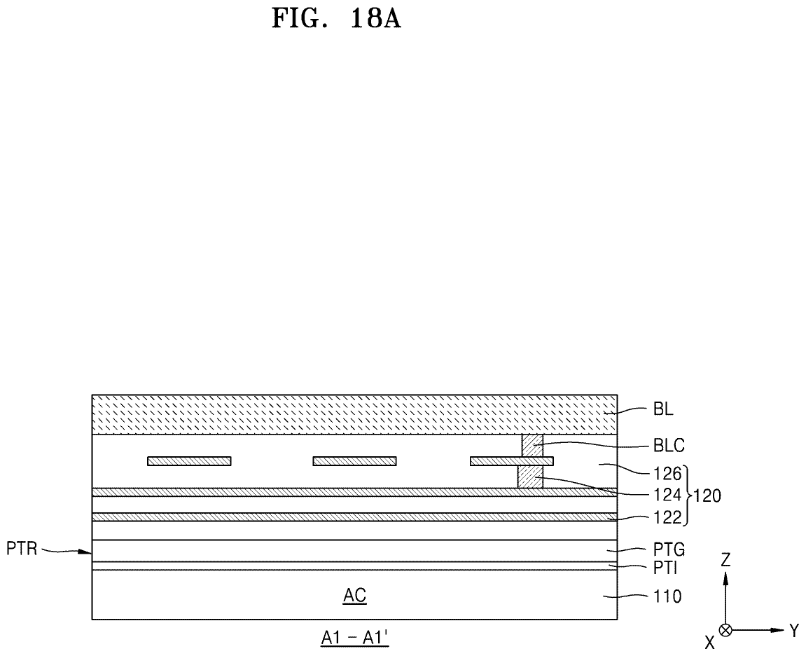

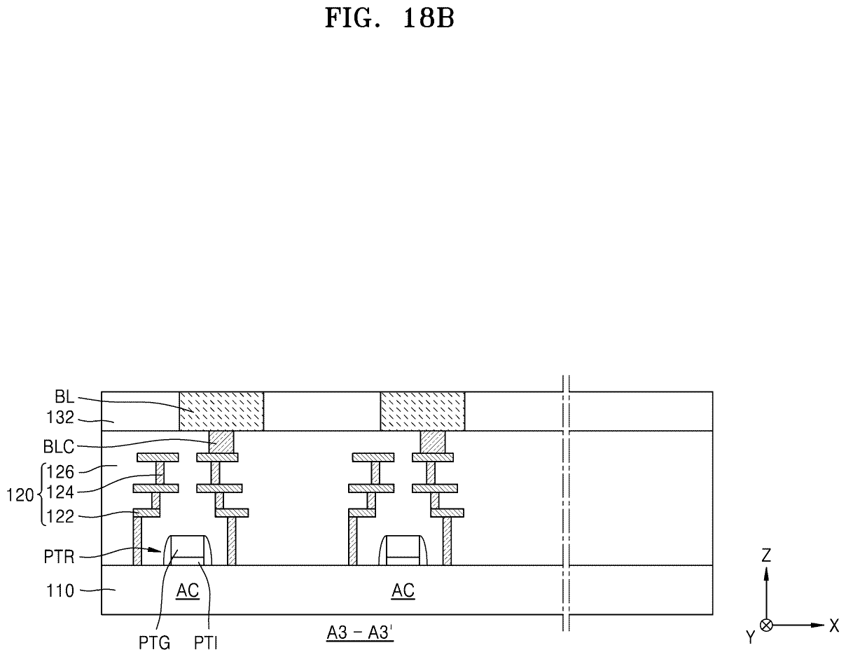

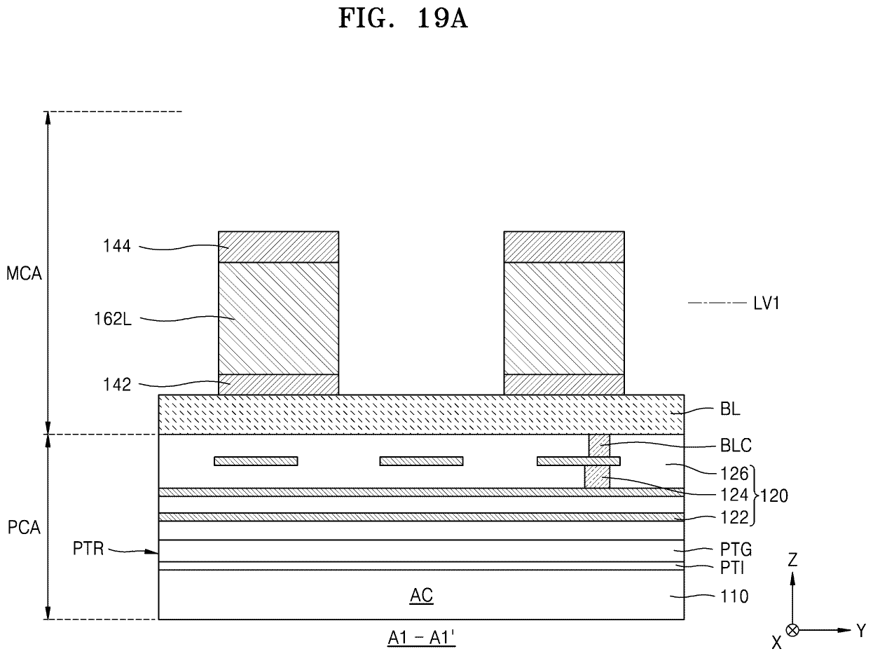

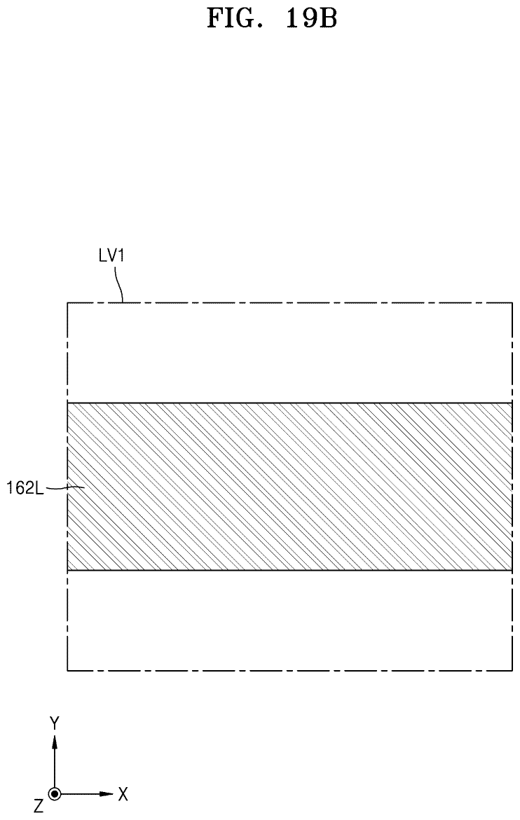

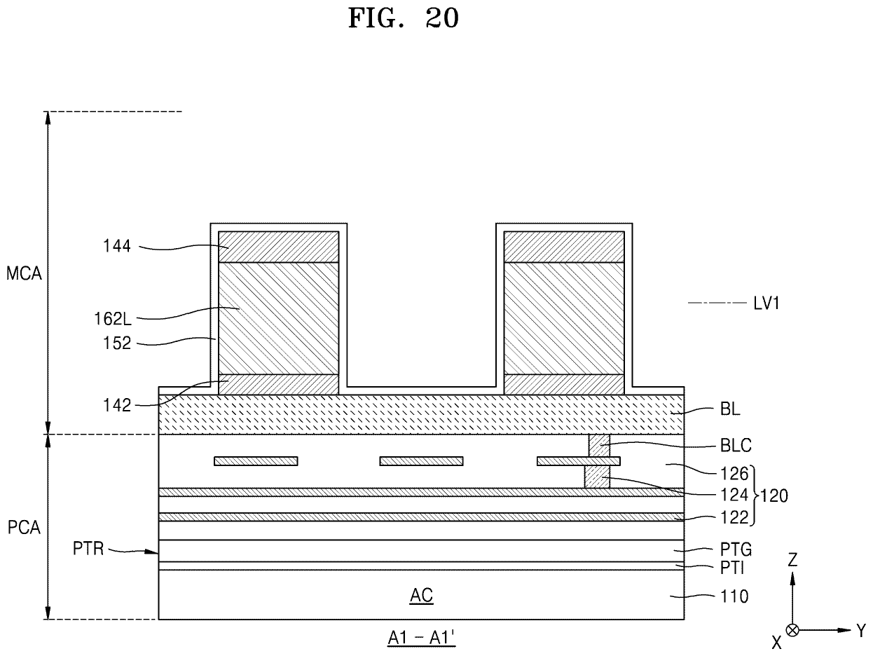

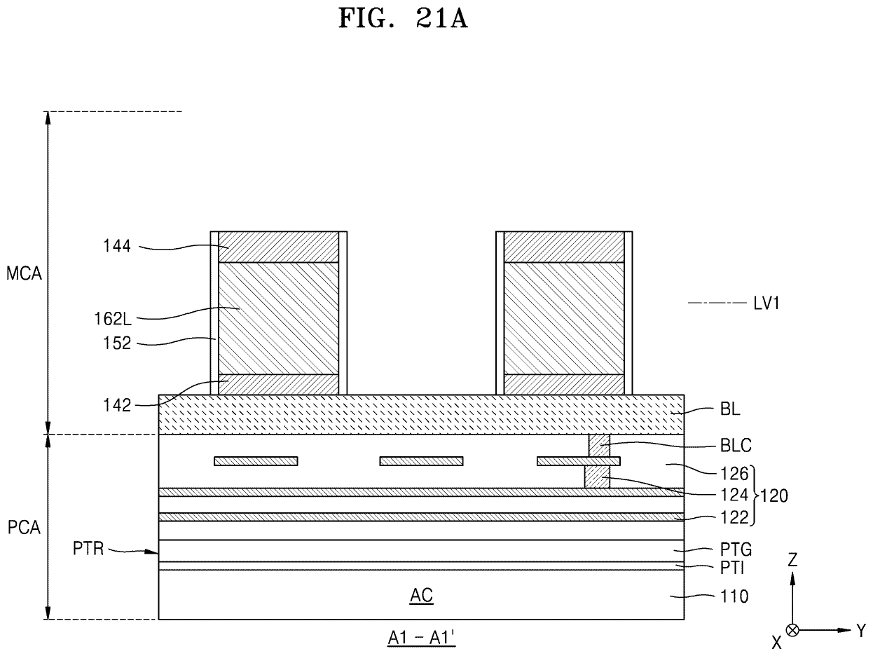

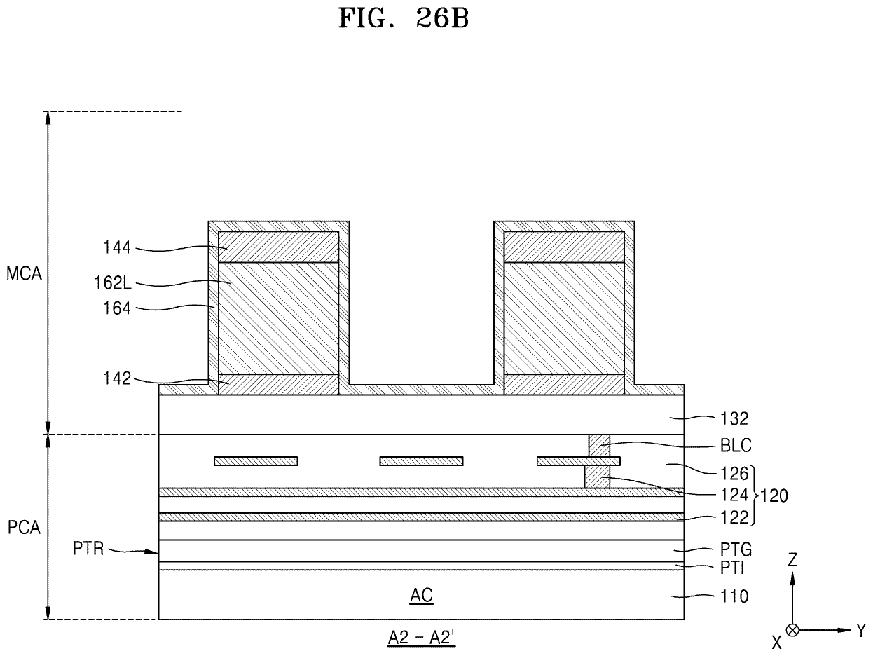

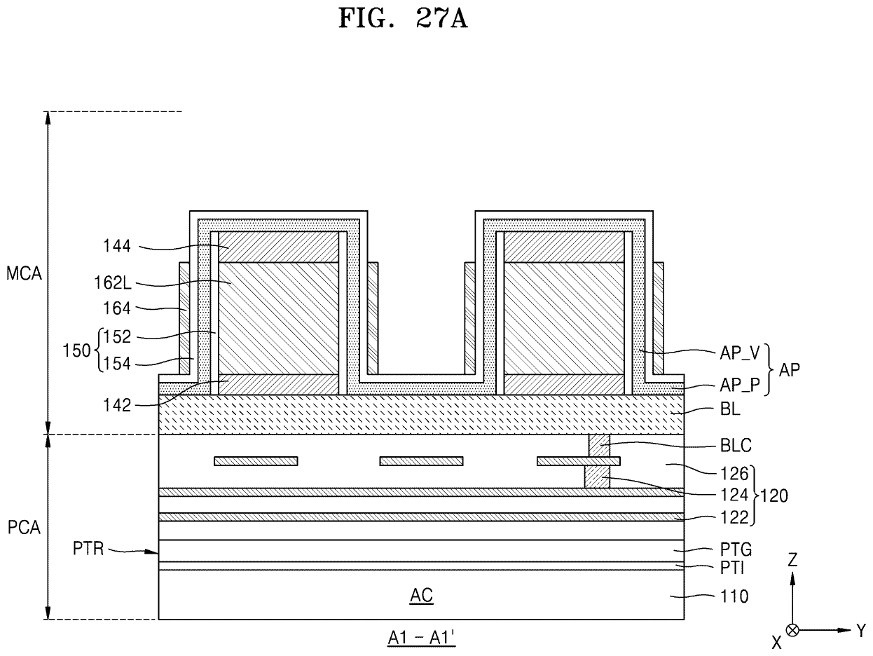

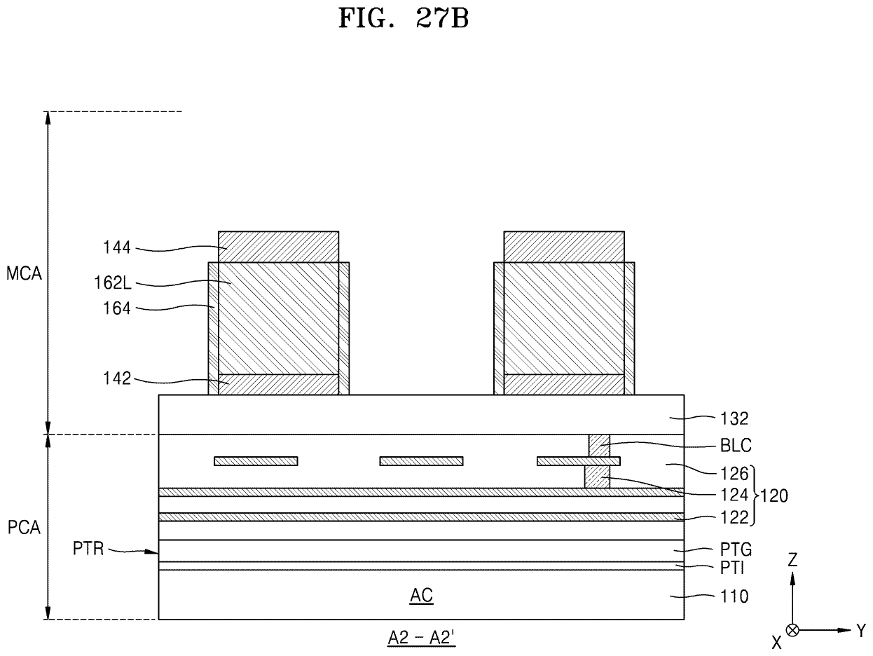

FIGS. 17 to 33 are schematic views showing a method of manufacturing the semiconductor device 100, according to some embodiments. FIGS. 18A, 19A, 20, 21A, 22A, 23A, 24A, 25A, 26A, 27A, 28A, 29A, 31, 32, and 33 are cross-sectional views taken along the line A1-A1′ of FIG. 3, FIGS. 26B and 27B are cross-sectional views taken along the line A2-A2′ of FIG. 3, FIGS. 17, 18B, 22B, 23B, 24B, 25B, 29B, and 30 are cross-sectional views taken along the line A3-A3′ of FIG. 3, and FIGS. 19B, 21B, 23C, 24C, 25C, and 28B are each a plan view at the first vertical level LV1 of FIG. 19A.

Referring to FIG. 17, the active area AC may be formed on the substrate 110, and the peripheral circuit transistor PTR may be formed on the active area AC. For example, the peripheral circuit transistor PTR may include the gate electrode PTG and the gate insulating layer PTI.

Thereafter, the peripheral circuit wiring 122 and the peripheral circuit contact 124, which are electrically connected to the substrate 110 and the peripheral circuit transistor PTR, may be formed, and the peripheral circuit insulating layer 126 covering the peripheral circuit wiring 122 and the peripheral circuit contact 124 may be formed on the substrate 110. The peripheral circuit insulating layer 126 may be formed using an oxide film, a nitride film, a low dielectric film, or a combination thereof.

The peripheral circuit contact 124 disposed at the highest position among peripheral circuit contacts 124 may be referred to as the bit line contact BLC. A top surface of the bit line contact BLC may be coplanar with an uppermost surface of the peripheral circuit insulating layer 126.

Referring to FIGS. 18A and 18B, the plurality of bit lines BL and the first insulating layer 132 may be formed on the peripheral circuit insulating layer 126.

In some embodiments, a conductive layer may be formed on the peripheral circuit insulating layer 126, and the plurality of bit lines BL may be formed by patterning the conductive layer. Thereafter, the first insulating layer 132, which fills a space between the plurality of bit lines BL, may be formed.

In some embodiments, the plurality of bit lines BL may be formed using a chemical vapor deposition process or an atomic layer deposition process, using Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof. In some embodiments, the first insulating layer 132 may be formed using at least one of silicon oxide, silicon oxynitride, or silicon nitride.

Referring to FIGS. 19A and 19B, the lower mold layer 142 and a metal mold layer 162L, and the upper mold layer 144 may be sequentially formed on the plurality of bit lines BL and the first insulating layer 132.

In some embodiments, an insulating layer for a lower mold, a conductive layer for a metal mold, and an insulating layer for an upper mold may be sequentially formed, after which a mask pattern may be formed on the insulating layer for the upper mold, and by using the mask pattern, the insulating layer for the lower mold, the conductive layer for the metal mold, and the insulating layer for the upper mold may be patterned, thereby forming the lower mold layer 142, the metal mold layer 162L, and the upper mold layer 144.

In some embodiments, each of the lower mold layer 142, the metal mold layer 162L, and the upper mold layer 144 may have a line pattern shape extending in the first horizontal direction X. The lower mold layer 142, the metal mold layer 162L, and the upper mold layer 144 may have side walls that are aligned with one another. In this regard, the lower mold layer 142, the metal mold layer 162L, and the upper mold layer 144 may be collectively referred to as a mold pattern.

In some embodiments, the metal mold layer 162L may be formed using Ti, TiN, Ta, TaN, Mo, Ru, W, WN, TiSiN, WSiN, polysilicon, or a combination thereof. In some embodiments, the lower mold layer 142 and the upper mold layer 144 may be formed using at least one of silicon oxide, silicon nitride, silicon oxynitride, or a low-k dielectric material.

Referring to FIG. 20, the first gate insulating layer 152 may be formed on a top surface and side wall of the mold pattern including the lower mold layer 142, the metal mold layer 162L, and the upper mold layer 144. The first gate insulating layer 152 may also be conformally arranged on top surfaces of the bit line BL and the first insulating layer 132.

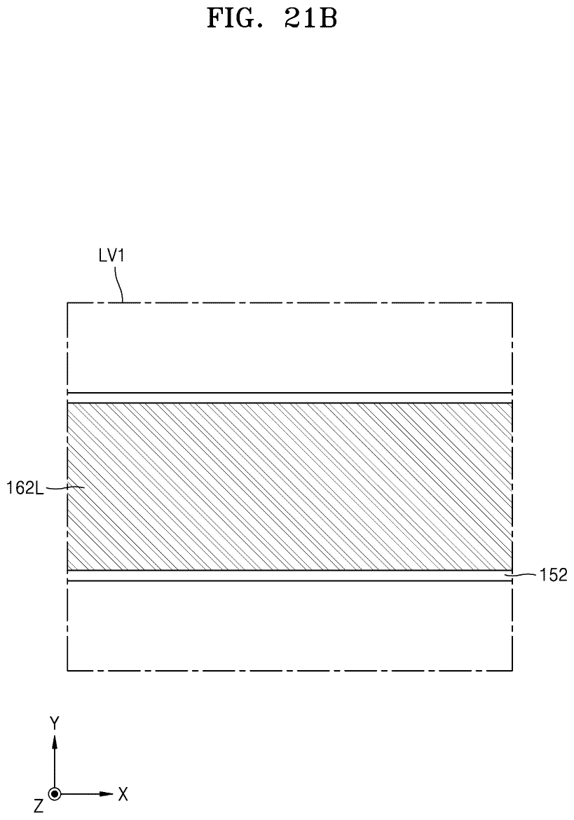

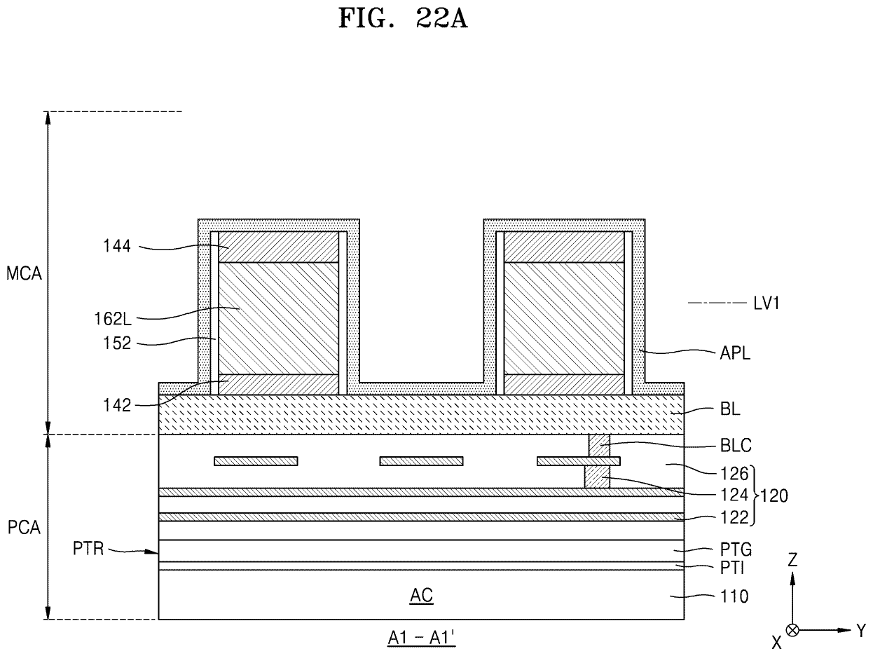

Referring to FIGS. 21A and 21B, an anisotropic etching process may be performed on the first gate insulating layer 152 to remove a portion of the first gate insulating layer 152 arranged on a top surface of the mold pattern (for example, a top surface of the upper mold layer 144), while leaving only a portion of the first gate insulating layer 152 arranged on a side wall of the mold pattern. In the anisotropic etching process, a portion of the first gate insulating layer 152 arranged on top surfaces of the bit line BL and the first insulating layer 132 may also be removed.

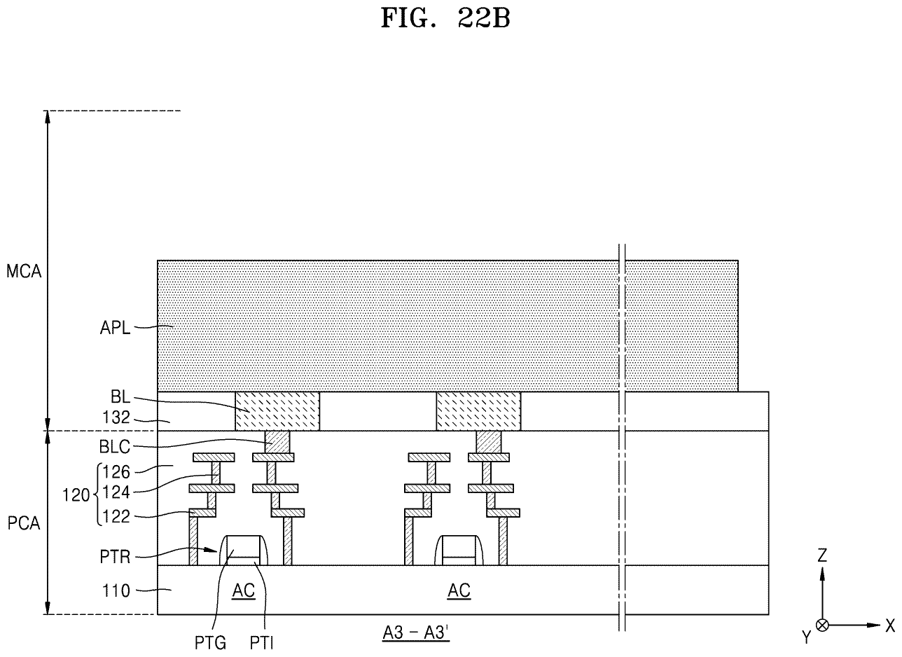

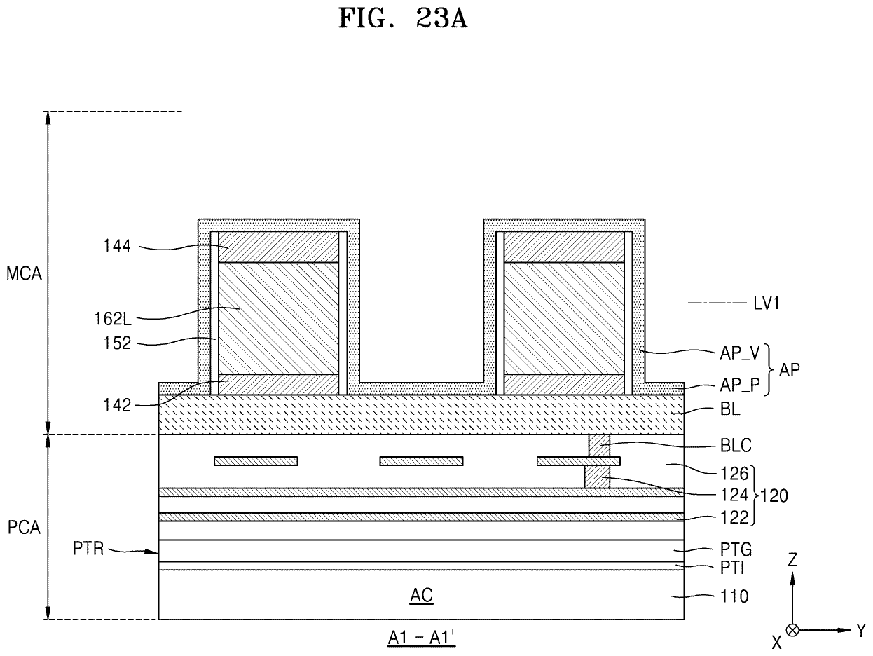

Referring to FIGS. 22A and 22B, an active material layer APL may be formed on a top surface and side wall of the mold pattern including the lower mold layer 142, the metal mold layer 162L, and the upper mold layer 144. In some embodiments, the active material layer APL may be conformally arranged on the side wall and top surface of the mold pattern and on top surfaces of the plurality of bit lines BL and the first insulating layer 132.

In some embodiments, the active material layer APL may be formed using at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), or silicon.

In some embodiments, the active material layer APL may be formed by a chemical vapor deposition (CVD) process, a plasma-enhanced CVD (PECVD) process, an atomic layer deposition (ALD) process, or a plasma-enhanced ALD (PEALD) process.

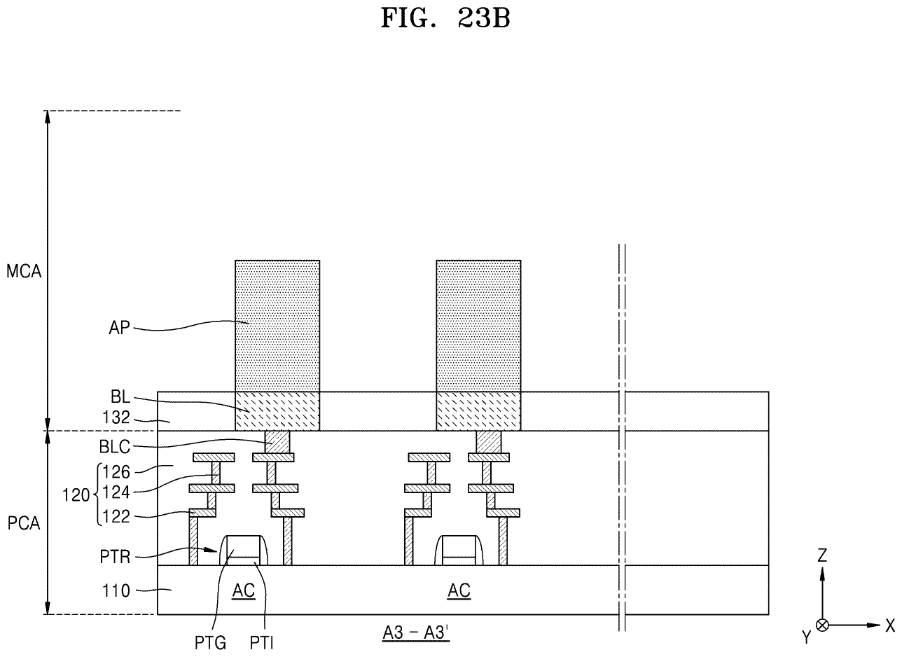

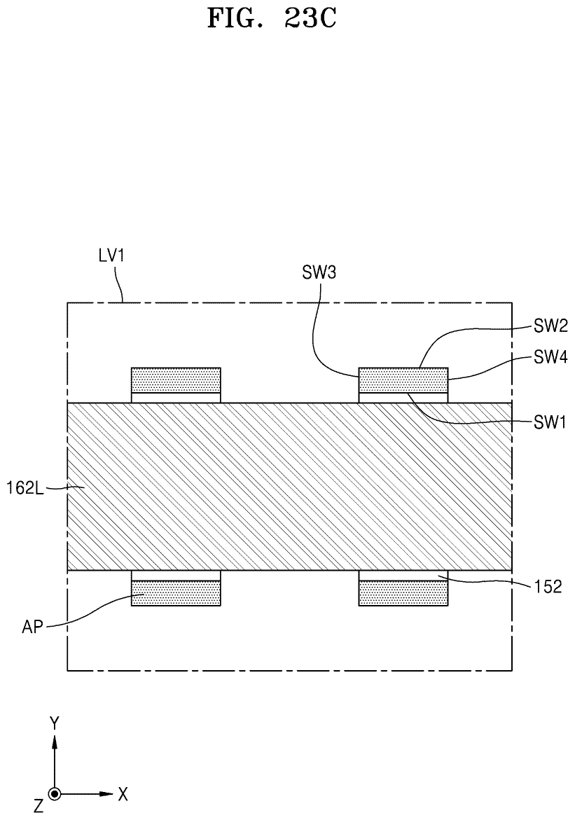

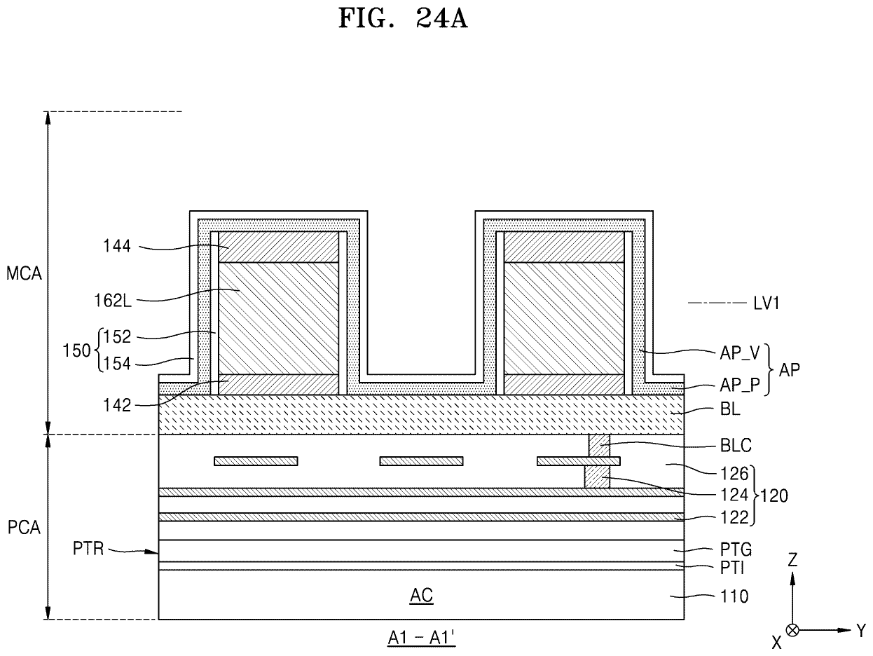

Referring to FIGS. 23A to 23C, a mask pattern extending in the second horizontal direction Y may be formed on the active material layer APL. Afterwards, a portion of the active material layer APL may be removed by using the mask pattern as an etching mask. Accordingly, the active material layer APL may extend in the second horizontal direction Y along a top surface and side wall of the mold pattern. A portion of the active material layer APL remaining after the removal process may be referred to as the active pattern AP.

The active pattern AP may include the vertical extension portion AP_V arranged on a side wall of the mold pattern and the horizontal extension portion AP_P arranged on a top surface of the bit line BL.

In some embodiments, a portion of the first gate insulating layer 152 arranged on a side wall of the mold pattern may also be removed in the etching process for removing a portion of the active material layer APL. Accordingly, the first gate insulating layer 152 may be arranged between the first side wall SW1 of the vertical extension portion AP_V and the side wall of the mold pattern (for example, a side wall of the lower mold layer 142, a side wall of the metal mold layer 162L, and a side wall of the upper mold layer 144).

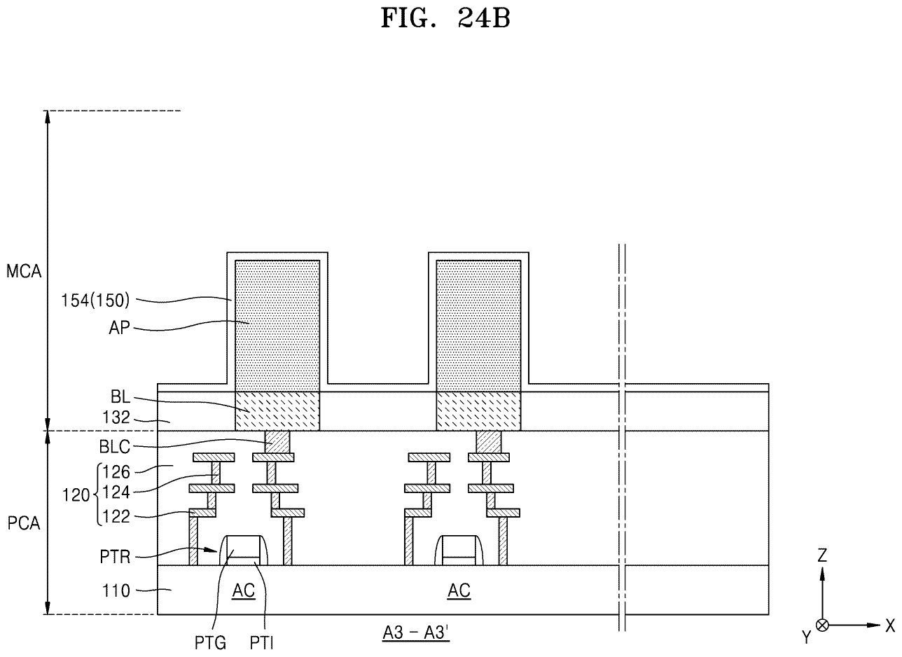

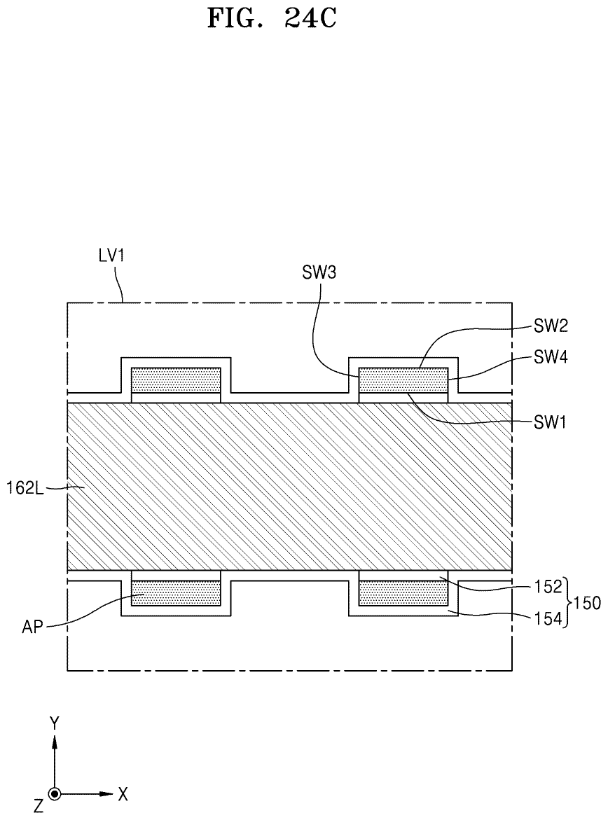

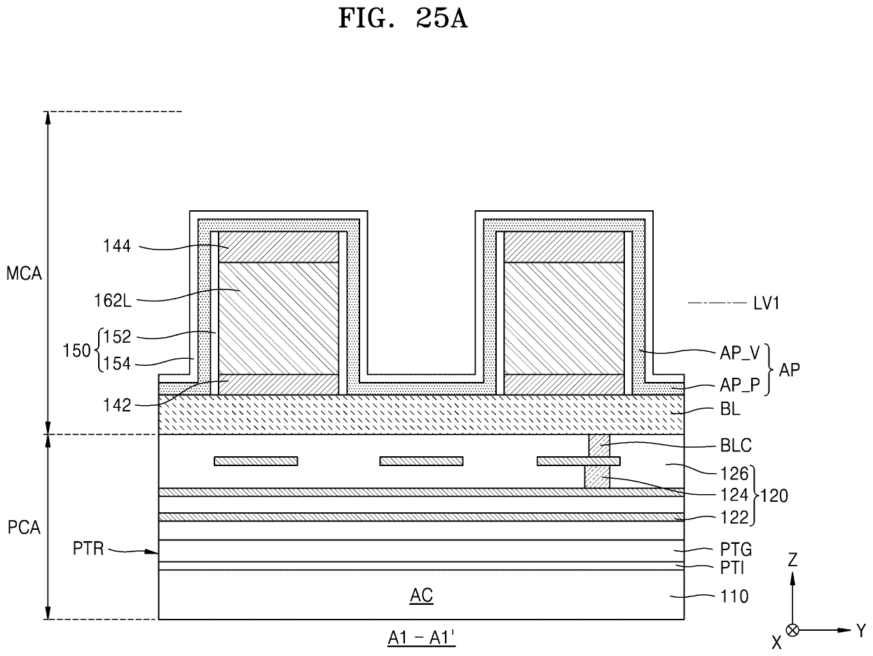

Referring to FIGS. 24A to 24C, the second gate insulating layer 154 covering the active pattern AP may be formed on a top surface and side wall of the mold pattern. The second gate insulating layer 154 may cover the second side wall SW2, the third side wall SW3, and the fourth side wall SW4 of the vertical extension portion AP_V and may be arranged on a top surface of the horizontal extension portion AP_P.

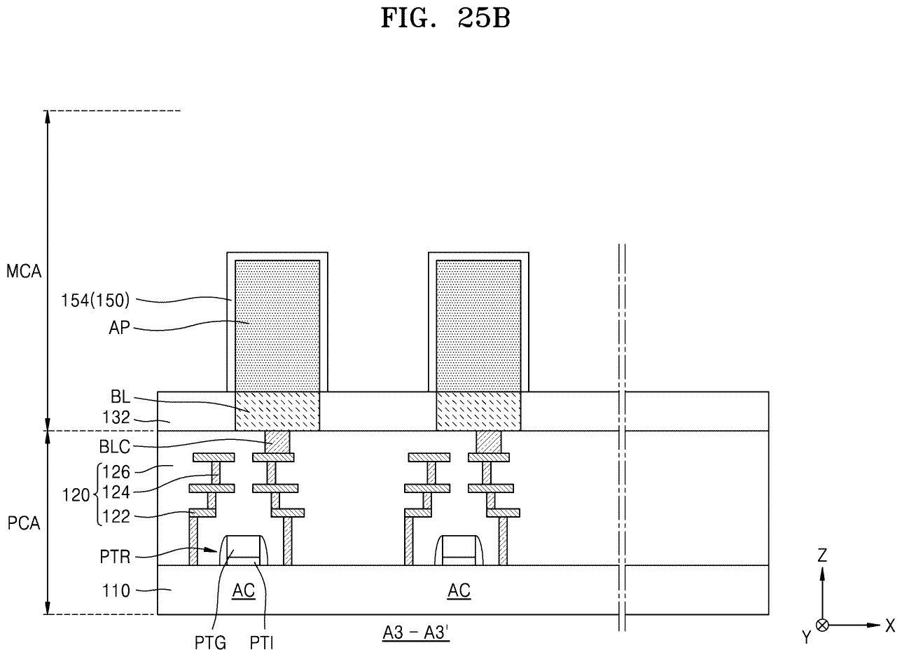

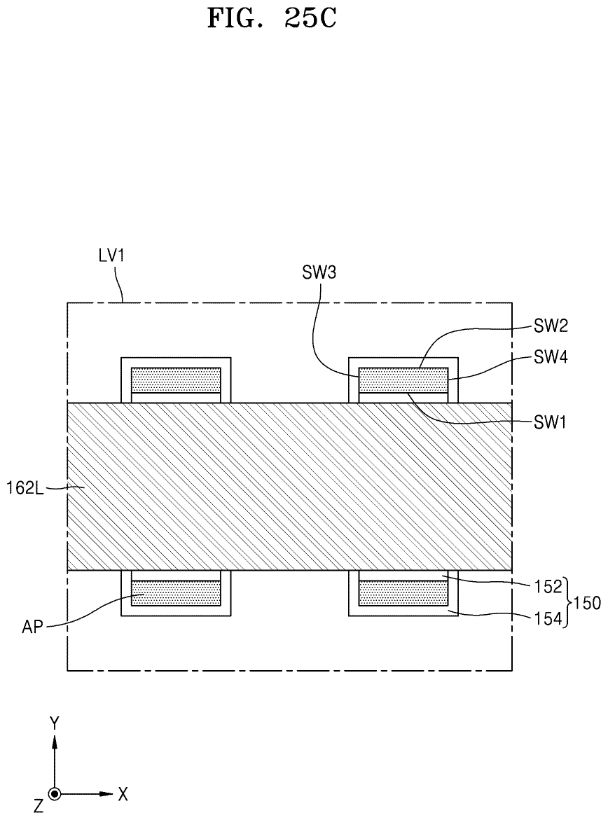

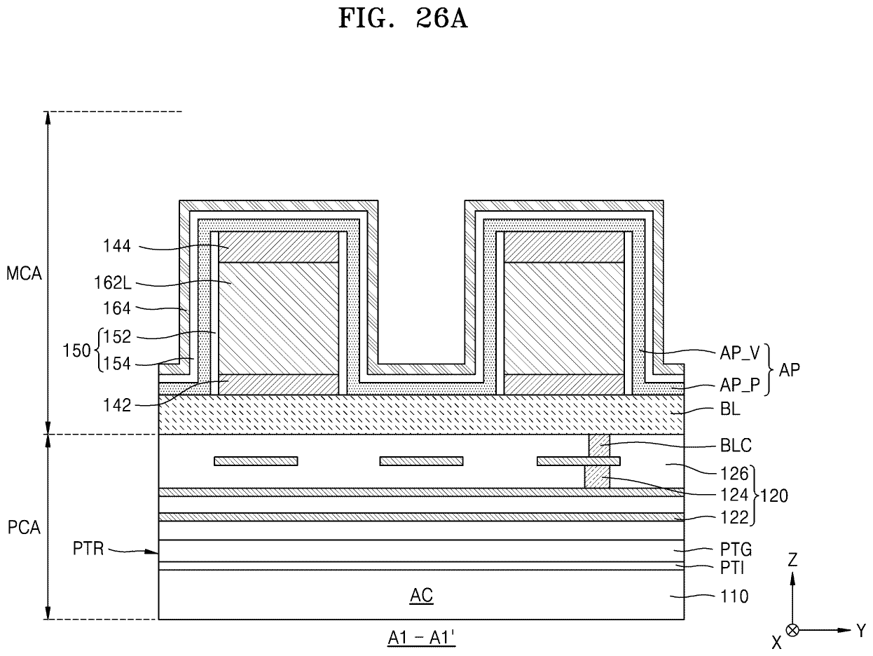

Referring to FIGS. 25A to 25C, a mask pattern extending in the second horizontal direction Y may be formed on a top surface of the second gate insulating layer 154, after which the mask pattern may be used as an etching mask to remove a portion of the second gate insulating layer 154 arranged on a side wall of the mold pattern, while leaving only a portion of the second gate insulating layer 154 covering the active pattern AP.

In some embodiments, the second gate insulating layer 154 may extend in the second horizontal direction Y along a top surface and side wall of the mold pattern. The second gate insulating layer 154 may be arranged to cover the second side wall SW2, the third side wall SW3, and the fourth side wall SW4 of the vertical extension portion AP_V of the active pattern AP.

Referring to FIGS. 26A and 26B, the second conductive layer 164 may be formed on a top surface and side wall of the mold pattern and on a side wall and top surface of the second gate insulating layer 154.

In some embodiments, the second conductive layer 164 may be formed using Ti, TiN, Ta, TaN, Mo, Ru, W, WN, TiSiN, WSiN, polysilicon, or a combination thereof.

Referring to FIGS. 27A and 27B, an anisotropic etching process may be performed to leave the second conductive layer 164 on a side wall of the mold pattern and on a side wall of the second gate insulating layer 154. As a result of this process, a portion of the second conductive layer 164 arranged on a top surface of the mold pattern and a top surface of the second gate insulating layer 154 may be removed.

In addition, an anisotropic etching process or a recess process may be performed to remove a portion of an upper side of the second conductive layer 164. In some embodiments, a top-surface level of the second conductive layer 164 may be formed to be substantially the same as a top-surface level of the metal mold layer 162L, and a side wall of the upper mold layer 144 may be exposed without being covered by the second conductive layer 164.

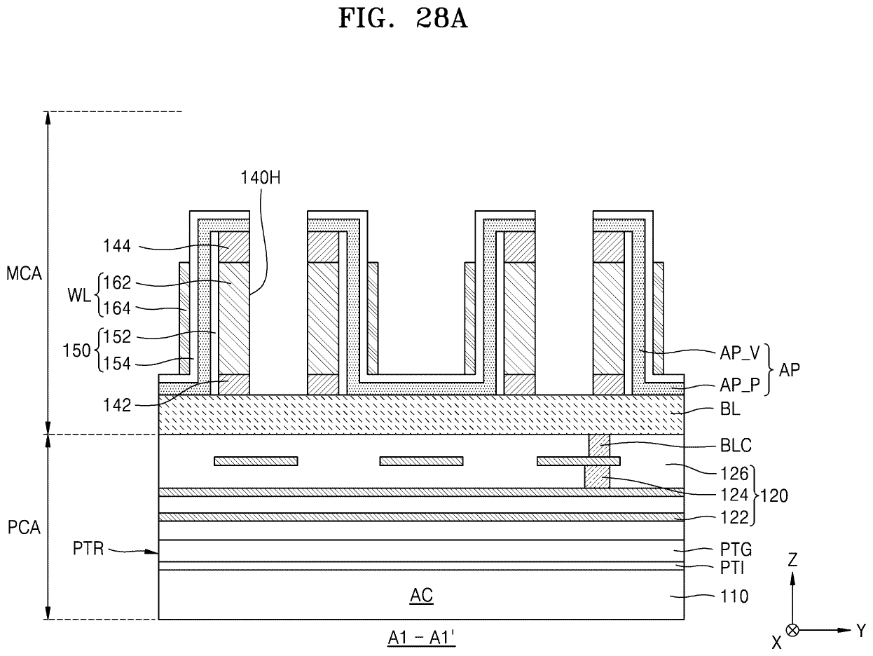

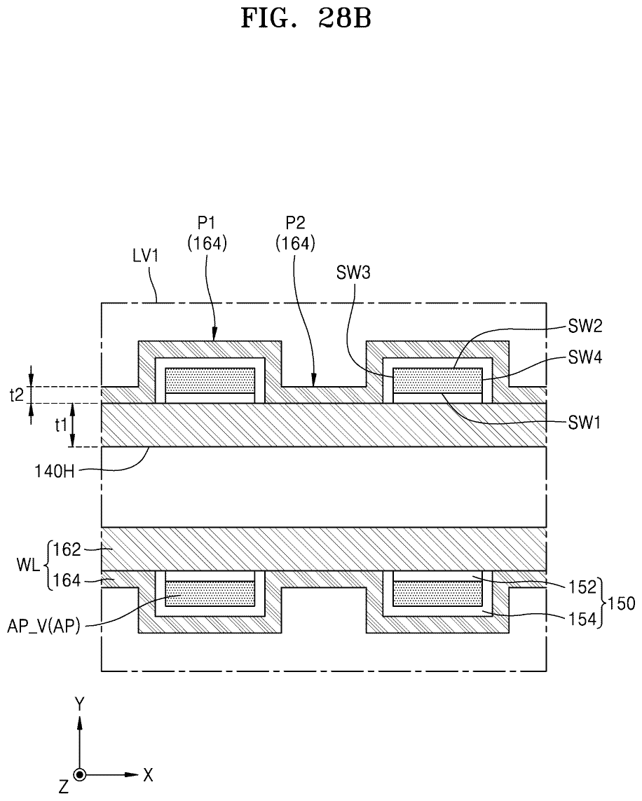

Referring to FIGS. 28A and 28B, a mask pattern extending in the first horizontal direction X may be formed on the mold pattern, and the mask pattern may be used as an etching mask to remove a portion of the mold pattern (for example, a portion of the upper mold layer 144, a portion of the metal mold layer 162L, and a portion of the lower mold layer 142), thereby forming a mold separation opening 140H. The mold separation opening 140H may extend from the cell array area MCA to the interface area IA.

In some embodiments, as the mold separation opening 140H is formed, one metal mold layer 162L may be separated into two first conductive layers 162 spaced apart from each other in the second horizontal direction Y. As the mold separation opening 140H is formed, a side wall of the upper mold layer 144, a side wall of the first conductive layer 162, and a side wall of the lower mold layer 142, which are exposed in the mold separation opening 140H, may be arranged in alignment with one another.

In some embodiments, the first thickness t1 (or the width in the second horizontal direction Y) of the first conductive layer 162 may be determined according to the width of the mold separation opening 140H. In some embodiments, the first thickness t1 of the first conductive layer 162 may be greater than the second thickness t2 of the second conductive layer 164, but disclosed concepts is not limited thereto.

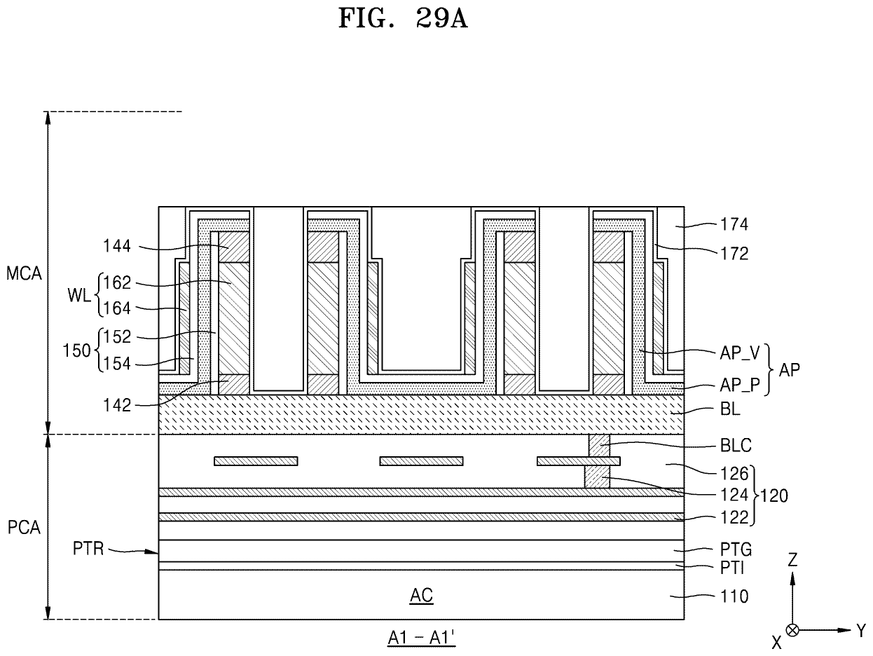

Referring to FIGS. 29A and 29B, the insulating liner 172 may be formed on an inner wall of the mold separation opening 140H and a side wall and top surface of the second conductive layer 164, and the buried insulating layer 174 may be formed on a top surface of the insulating liner 172. As shown in FIG. 29B, the insulating liner 172 and the buried insulating layer 174 may be arranged even on the first conductive layer 162 and the second conductive layer 164, which are arranged in the interface area IA.

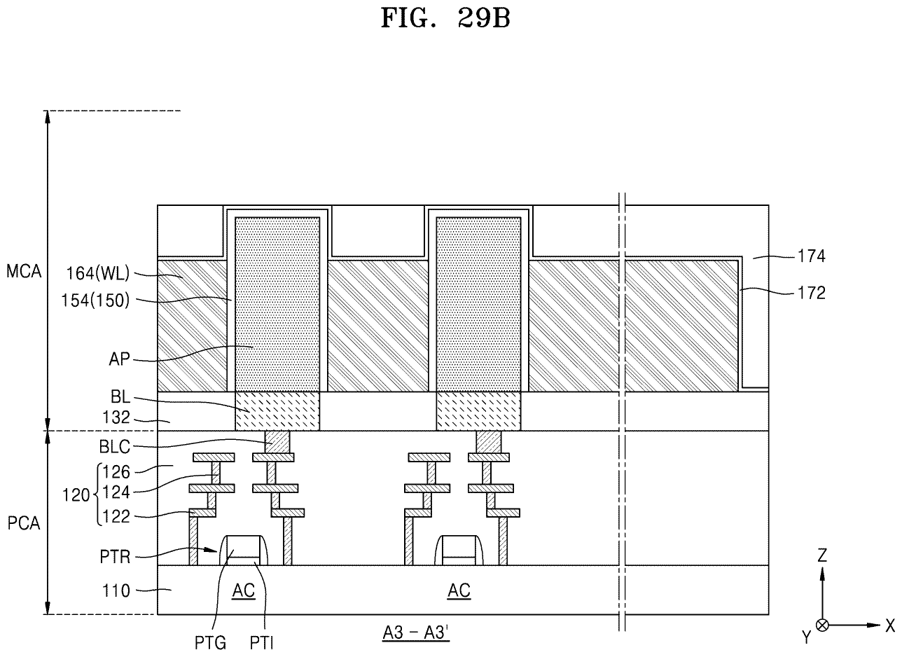

Referring to FIG. 30, a word line contact hole WLCH is formed by removing a portion of the buried insulating layer 174 arranged in the interface area IA. Top surfaces of the first conductive layer 162 and the second conductive layer 164 may be exposed at a bottom portion of the word line contact hole WLCH. Thereafter, the word line contact WLC may be formed inside the word line contact hole WLCH by using a conductive material.

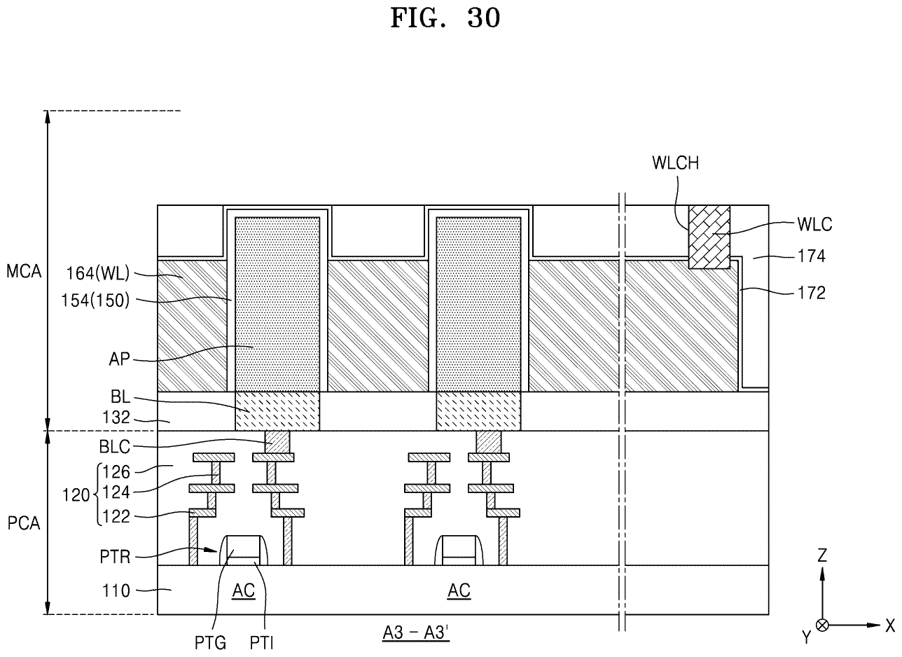

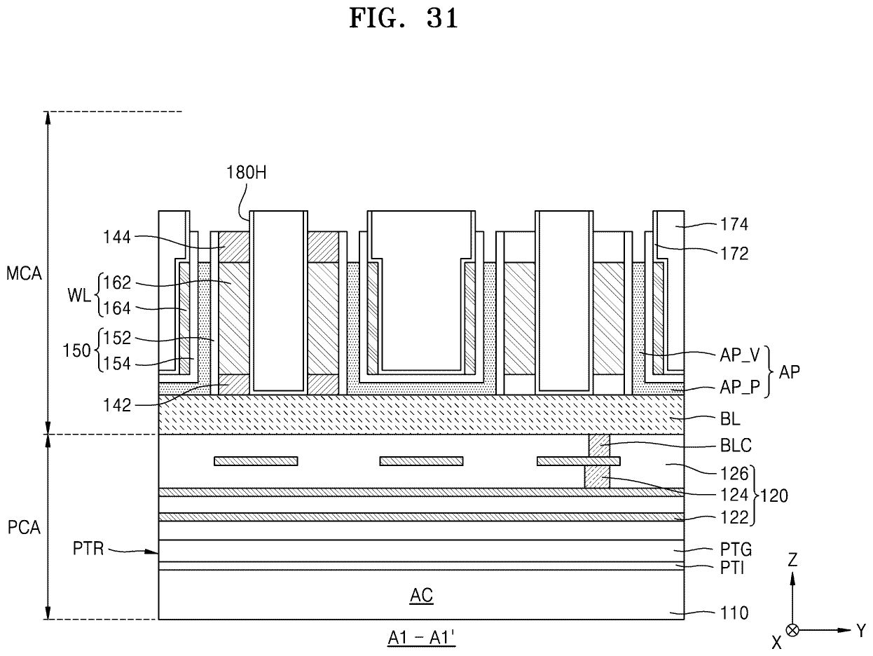

Referring to FIG. 31, a portion of the second gate insulating layer 154 arranged on a top surface of the upper mold layer 144 may be removed, and then a portion of the active pattern AP arranged on the top surface of the upper mold layer 144 may be removed, thereby forming the landing pad opening 180H.

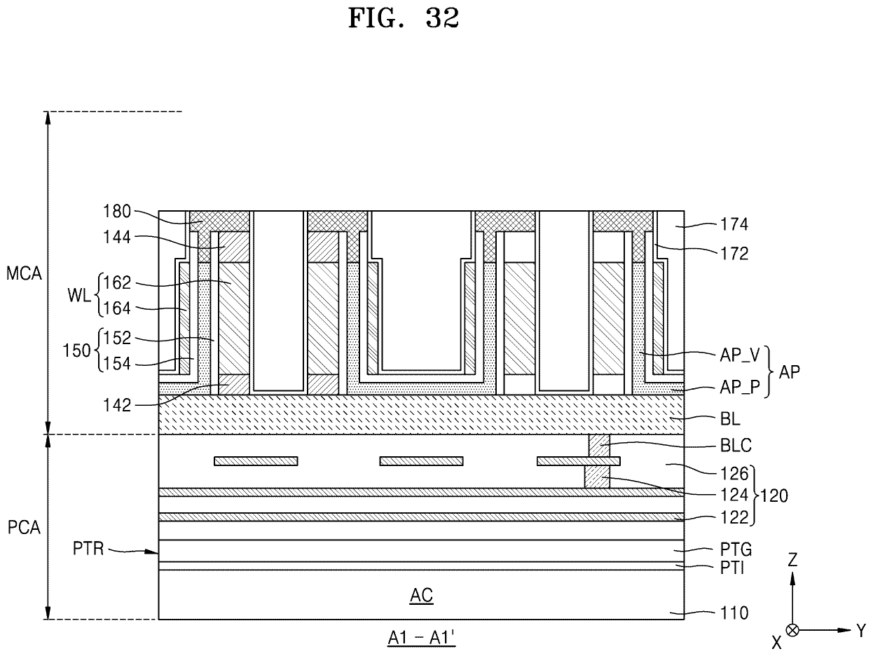

Referring to FIG. 32, the landing pad 180 may be formed in the landing pad opening 180H by using at least one of Ti, TiN, Ta, TaN, W, WN, TiSiN, WSiN, or polysilicon. The landing pad 180 may have a bottom surface that is in contact with a top surface of the active pattern AP. In addition, a portion of the landing pad 180 may be arranged on a top surface of the upper mold layer 144 such that the width of an upper side of the landing pad 180 may be greater than the width of a bottom portion thereof.

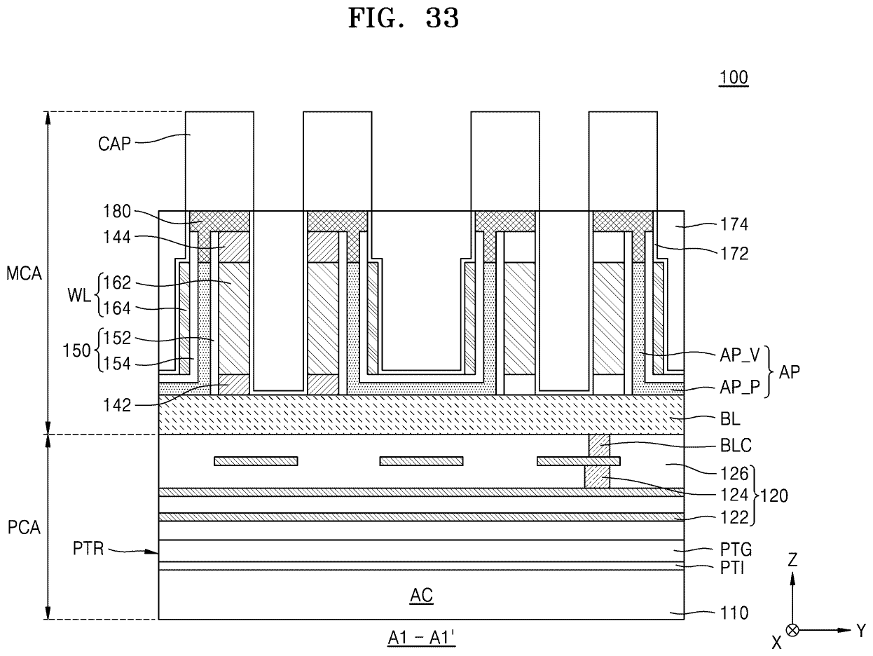

Referring to FIG. 33, the cell capacitor CAP may be formed on the landing pad 180.

The semiconductor device 100 may be completed by performing the aforementioned process.

According to some embodiments, the active pattern AP may be formed on a side wall of the metal mold layer 162L, after which the second conductive layer 164 may be formed on a side wall of the active pattern AP, and by separating the metal mold layer 162L into two first conductive layers 162, a cell transistor may be formed. According to this manufacturing method, a GAA-type cell transistor may be formed through a simplified process. The semiconductor device 100 may have excellent electrical performance such as reduced leakage current and increased cell operating current.

According to the disclosed concepts, a semiconductor device may include a GAA-type cell transistor, and electrical performance of the cell transistor may be improved, for example, by a decrease in leakage current of the cell transistor and an increase in cell operating current.

According to aspects of the disclosed concepts, there is provided a method of manufacturing a semiconductor device, the method including forming a plurality of bit lines extending in a first horizontal direction on a substrate, forming a first conductive layer extending in a second horizontal direction on the plurality of bit lines, forming a plurality of active patterns extending in a vertical direction on a side wall of the first conductive layer and spaced apart from each other in the second horizontal direction, the plurality of active patterns each including a first side wall facing the side wall of the first conductive layer and a second side wall opposite to the first side wall, forming a second conductive layer on the side wall of the first conductive layer and on the second side wall of each of the plurality of active patterns, and forming a plurality of cell capacitors respectively on the plurality of active patterns.

In some embodiments, the second conductive layer may include a first portion arranged on the second side wall of each of the plurality of active patterns and a second portion arranged on the side wall of the first conductive layer.

In some embodiments, the method may further include forming a first gate insulating layer between the side wall of the first conductive layer and the first side wall of each of the plurality of active patterns, and forming a second gate insulating layer between the first portion of the second conductive layer and the second side wall of each of the plurality of active patterns.

In some embodiments, each of the plurality of active patterns may further include a third side wall that is connected to the first side wall and the second side wall, and a fourth side wall that is connected to the first side wall and the second side wall and is opposite to the third side wall, and forming of the second gate insulating layer may include forming the second gate insulating layer on the second side wall, the third side wall, and the fourth side wall of each of the plurality of active patterns.

In some embodiments, the second gate insulating layer may be in contact with the first gate insulating layer, and in a plan view, the first gate insulating layer and the second gate insulating layer may collectively surround each of the plurality of active patterns.

In some embodiments, the plurality of active patterns may extend in the vertical direction and may each include a vertical extension portion including the first side wall and the second side wall, and a horizontal extension portion connected to a bottom portion of the vertical extension portion and extending in the first horizontal direction, the first gate insulating layer may be arranged between the first side wall of the vertical extension portion and the first conductive layer, and the second gate insulating layer may be arranged between the second side wall of the vertical extension portion and the first portion of the second conductive layer and may extend onto a top surface of the horizontal extension portion.

In some embodiments, the first conductive layer may have a first thickness in the first horizontal direction, the second conductive layer may have a second thickness in the first horizontal direction, and the second thickness may be less than the first thickness.

In some embodiments, the method may further include forming a lower mold layer extending in the second horizontal direction on the plurality of bit lines and having a top surface that is in contact with a bottom surface of the first conductive layer, and forming an upper mold layer arranged on a top surface of the first conductive layer and extending in the second horizontal direction.

In some embodiments, each of the plurality of active patterns may include a vertical extension portion arranged on a side wall of the lower mold layer, the side wall of the first conductive layer, and a side wall of the upper mold layer, and a horizontal extension portion connected to a bottom portion of the vertical extension portion, extending in the first horizontal direction, and arranged on the plurality of bit lines.

In some embodiments, the method may further include forming a first gate insulating layer between the vertical extension portion of each of the plurality of active patterns and the side wall of the lower mold layer, the side wall of the first conductive layer, and the side wall of the upper mold layer.

While the disclosed concepts have been particularly shown and described with reference to embodiments thereof, it will be understood that various changes in form and details may be made therein without departing from the spirit and scope of the following claims.

What is claimed is:

1. A semiconductor device comprising:
a peripheral circuit area; and
a cell array area arranged on the peripheral circuit area, wherein the cell array area comprises:
a plurality of bit lines extending in a first horizontal direction;
a plurality of active patterns extending in a vertical direction on the plurality of bit lines and each comprising a first side wall and a second side wall opposite to the first side wall;
a word line extending in a second horizontal direction crossing the first horizontal direction on the plurality of bit lines, and comprising:
a first conductive layer arranged on the first side wall of each of the plurality of active patterns and extending in the second horizontal direction, and
a second conductive layer comprising a first portion arranged on the second side wall of each of the plurality of active patterns and comprising a second portion arranged on a side wall of the first conductive layer; and
a plurality of cell capacitors arranged on the plurality of active patterns.

2. The semiconductor device of claim 1, wherein, in a plan view, the word line surrounds the plurality of active patterns and extends in the second horizontal direction.

3. The semiconductor device of claim 1, wherein:
each of the plurality of active patterns is arranged between the first portion of the second conductive layer and the first conductive layer, and
the second portion of the second conductive layer is in contact with the side wall of the first conductive layer.

4. The semiconductor device of claim 1, further comprising
a plurality of gate insulating layer structures arranged between the word line and each of the plurality of active patterns and comprising:
a first gate insulating layer arranged between the first side wall of each of the plurality of active patterns and the first conductive layer; and
a second gate insulating layer arranged between the second side wall of each of the plurality of active patterns and the first portion of the second conductive layer.

5. The semiconductor device of claim 4, wherein:
the plurality of active patterns extend in the vertical direction and each comprise a vertical extension portion comprising the first side wall and the second side wall, and
a horizontal extension portion connected to a bottom portion of the vertical extension portion and extending in the first horizontal direction,
the first gate insulating layer is arranged between the first side wall of the vertical extension portion and the first conductive layer, and
the second gate insulating layer is arranged between the second side wall of the vertical extension portion and the first portion of the second conductive layer and extends onto a top surface of the horizontal extension portion.

6. The semiconductor device of claim 5, wherein
the vertical extension portion further comprises:
a third side wall that is connected to the first side wall and the second side wall; and
a fourth side wall that is connected to the first side wall and the second side wall and is opposite to the third side wall, and
the second gate insulating layer extends onto the third side wall and the fourth side wall and is in contact with the first gate insulating layer.

7. The semiconductor device of claim 6, wherein,
in a plan view, the first gate insulating layer and the second gate insulating layer collectively surround the vertical extension portion.

8. The semiconductor device of claim 6, wherein:
a portion of the second gate insulating layer is arranged between the first portion of the second conductive layer and the third side wall of the vertical extension portion, and
a portion of the second gate insulating layer is arranged between the first portion of the second conductive layer and the fourth side wall of the vertical extension portion.

9. The semiconductor device of claim 1, wherein
the plurality of active patterns comprise at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), magnesium aluminum zinc oxide (MgₓAl_{y}Zn_{z}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), or silicon.

10. The semiconductor device of claim 1, wherein:
the first conductive layer has a first thickness in the first horizontal direction,
the second conductive layer has a second thickness in the first horizontal direction, and
the second thickness is less than the first thickness.

11. The semiconductor device of claim 1, further comprising:
a lower mold layer extending in the second horizontal direction on the plurality of bit lines and having a top surface that is in contact with a bottom surface of the first conductive layer; and
an upper mold layer arranged on a top surface of the first conductive layer and extending in the second horizontal direction.

12. The semiconductor device of claim 11, wherein:
opposite side walls of the lower mold layer are aligned with opposite side walls of the first conductive layer, and
opposite side walls of the upper mold layer are aligned with the opposite side walls of the first conductive layer.

13. The semiconductor device of claim 1, wherein a top surface of the second conductive layer is coplanar with a top surface of the first conductive layer.

14. The semiconductor device of claim 1, wherein a top surface of the second conductive layer is arranged at a vertical level that is higher than a vertical level of a top surface of the first conductive layer.

15. The semiconductor device of claim 1, wherein a top surface of the second conductive layer is arranged at a vertical level that is lower than a vertical level of a top surface of the first conductive layer.

16. A semiconductor device comprising:
a plurality of bit lines arranged on a substrate and extending in a first horizontal direction;
a plurality of active patterns extending in a vertical direction on the plurality of bit lines and each comprising a first side wall and a second side wall, which are opposite to each other, and a third side wall and a fourth side wall, which are opposite to each other;
a word line extending in a second horizontal direction crossing the first horizontal direction on the plurality of bit lines, and comprising:
a first conductive layer arranged on the first side wall of each of the plurality of active patterns and extending in the second horizontal direction, and
a second conductive layer comprising a first portion arranged on the second side wall, the third side wall, and the fourth side wall of each of the plurality of active patterns and extending in the second horizontal direction; and
a cell capacitor arranged on each of the plurality of active patterns.

17. The semiconductor device of claim 16, further comprising:
a plurality of gate insulating layer structures arranged between the word line and each of the plurality of active patterns and comprising
a first gate insulating layer arranged between the first side wall of each of the plurality of active patterns and the first conductive layer, and
a second gate insulating layer arranged between the second side wall of each of the plurality of active patterns and the first portion of the second conductive layer, between the third side wall and the first portion of the second conductive layer, and between the fourth side wall and the first portion of the second conductive layer.

18. The semiconductor device of claim 16, wherein the second conductive layer further comprises a second portion arranged on a side wall of the first conductive layer.

19. The semiconductor device of claim 16, further comprising:
a lower mold layer extending in the second horizontal direction on the plurality of bit lines and having a top surface that is in contact with a bottom surface of the first conductive layer; and
an upper mold layer arranged on a top surface of the first conductive layer and extending in the second horizontal direction,
wherein opposite side walls of the lower mold layer are aligned with opposite side walls of the first conductive layer, and
opposite side walls of the upper mold layer are aligned with the opposite side walls of the first conductive layer.

20. A semiconductor device comprising:
a peripheral circuit area; and
a cell array area arranged on the peripheral circuit area, wherein the cell array area comprises:
a plurality of bit lines extending in a first horizontal direction;
a plurality of active patterns extending in a vertical direction on the plurality of bit lines and each comprising a first side wall and a second side wall opposite to the first side wall;
a word line extending in a second horizontal direction crossing the first horizontal direction on the plurality of bit lines, and comprising
a first conductive layer arranged on the first side wall of each of the plurality of active patterns and extending in the second horizontal direction, and
a second conductive layer comprising a first portion arranged on the second side wall of each of the plurality of active patterns and a second portion arranged on a side wall of the first conductive layer, the second conductive layer extending in the second horizontal direction;
a plurality of gate insulating layer structures arranged between the word line and each of the plurality of active patterns and comprising
a first gate insulating layer arranged between the first side wall of each of the plurality of active patterns and the first conductive layer, and
a second gate insulating layer arranged between the second side wall of each of the plurality of active patterns and the first portion of the second conductive layer; and
a plurality of cell capacitors respectively arranged on the plurality of active patterns.
